(19) United States
(12) Patent Application Publication
(10) Pub. No.: US 2015/0255751 A1
(43) Pub. Date: Sep. 10, 2015

(54) OPTOELECTRONIC COMPONENT AND METHOD FOR PRODUCING AN OPTOELECTRONIC COMPONENT

(71) Applicant: OSRAM OLED GMBH, Regensburg (DE)

(72) Inventor: Philipp Schwamb, Regensburg (DE)

(21) Appl. No.: 14/431,838

(22) PCT Filed: Sep. 24, 2013
(86) PCT No.: PCT/EP2013/069785

§ 371 Date: Mar. 27, 2015

(30) Foreign Application Priority Data
Sep. 27, 2012 (DE) 10 2012 109 143.9

(51) Int. Cl. H01L 51/52; H01L 51/44; H01L 51/56

(52) U.S. Cl. CPC H01L 51/5259; H01L 51/5284; H01L 51/5275; H01L 51/5253; H01L 51/56; H01L 51/448; H01L 51/447

(57) ABSTRACT

An optoelectronic component may include a carrier, an organic functional layer structure, which is embodied on or above a carrier and is designed for taking up and/or providing electromagnetic radiation, an antireflection/getter layer structure arranged in the beam path of the organic functional layer structure and including getter material having a lower mean refractive index than the mean refractive index of the organic functional layer structure, and an antireflection layer, wherein material of the antireflection layer is arranged in the beam path of the organic functional layer structure at least partly between the organic functional layer structure and the getter material, and wherein the material of the antireflection layer arranged between the organic functional layer structure and the getter material has a mean refractive index which is greater than the refractive index of the getter material and/or comprises at least one scattering additive material distributed in a matrix.

### RELATED APPLICATIONS

The present application is a national stage entry according to 35 U.S.C. §371 of PCT application No. PCT/EP2013/069785 filed on Sep. 24, 2013, which claims priority from German application No. 10 2012 109 143.9 filed on Sep. 27, 2012, and is incorporated herein by reference in its entirety.

### TECHNICAL FIELD

In various embodiments, an optoelectronic component and a method for producing an optoelectronic component are provided.

### BACKGROUND

Optoelectronic components on an organic basis, for example an organic light emitting diodes (OLED) or an organic solar cell, are being increasingly widely used.

An OLED may include two electrodes, for example two contact metallization designed as an anode and a cathode, with an organic functional layer system therebetween. The organic functional layer system may include one or a plurality of emitter layer/s in which electromagnetic radiation is generated, for example, one or a plurality of charge generating layer structure each composed of two or more charge generating layers (CGL) for charge generation, and one or a plurality of electron blocking layers, also designated as hole transport layer(s) (HTL), and one or a plurality of hole blocking layers, also designated as electron transport layer(s) (ETL), in order to direct the current flow.

The organic functional layer system or at least one part thereof may include organic substances and/or organic substance mixtures. However, organic substances and/or organic substance mixtures can be susceptible to harmful environmental influences. A harmful environmental influence can be understood to mean all influences which can potentially lead to degradation or aging, for example a crosslinked state or crystallization, of organic substances and/or organic substance mixtures and can thus limit the operating period of the OLED, for example. A harmful environmental influence can be for example a substance harmful to organic substances or organic substance mixtures, for example oxygen and/or water.

In order to protect the organic functional layer system and the electrodes against harmful environmental influences, the organic, electronic component is encapsulated. During the encapsulation of an OLED, by way of example, the organic functional layer structure and the electrodes are surrounded with an encapsulation layer that is impermeable to harmful environmental influences, for example a thin film that is impermeable to water and oxygen (illustrated in FIGS. 6A and 6B).

FIGS. 6A and 6B show different configurations of a conventional optoelectronic component.

A first electrode 604 is embodied on a carrier 602. An organic functional layer structure 606 is embodied on the first electrode 604. A second electrode 608 is embodied on the organic functional layer structure 606. An encapsulation layer 610, 612 is embodied on the second electrode 608. This type of encapsulation is also designated as thin-film encapsulation.

The encapsulation layer 610, 612 is embodied in such a way that the encapsulation layer 610, 612 together with the carrier 602 completely surrounds the first electrode 604, the organic functional layer structure 606 and the second electrode 608—illustrated in FIG. 6A.

In a further conventional optoelectronic component—illustrated in FIG. 6B—the encapsulation layer 610, 612 can be structured—illustrated as encapsulation layer 610.

In the case of conventional optoelectronic components, the ambient moisture is in direct, whole-area contact with the encapsulation layer 610—correspondingly stringent requirements are therefore made of this encapsulation layer 610.

The encapsulation layer for thin-film-encapsulated organic light emitting diodes should be absolutely free of defects. In the course of encapsulation, however, the situation in which defects are still located in the encapsulation layer cannot be completely ruled out. Even a microscopic defect or a diffusion channel along a grain boundary in said encapsulation layer can lead for example to a defect of the entire OLED. As a result, non-luminous, circular points (black spot) can form in the field of view of the OLED by the action of moisture and can grow over the course of time.

In order that the potential damage for an OLED is kept small, in one conventional method a glass cover is applied to the encapsulation layer of a rigid optoelectronic component.

In another conventional method, a glass cover can be applied to the encapsulation layer for example by frit bonding (glass frit bonding/glass soldering/seal glass bonding) by a conventional glass solder in the geometrical edge regions.

In another conventional method, the glass cover can be applied by lamination by a laminating adhesive. In this case, the glass cover can be designed as a cavity glass and can be adhesively bonded, for example laminated, onto the OLED. The adhesive bonding is formed in the geometrical edge of the OLED. However, only the rate at which water diffuses into the OLED, for example, can be reduced by the glass cover. Water can for example still diffuse into the organic functional layer structure through the laminating adhesive, such that for example a defect in the encapsulation layer of an OLED is merely slowed down as it leads to a visible defect.

In one conventional method, a layer (getter layer) of a water-absorbing material (getter) is set up in the cavity of the cavity glass. The moisture, i.e. the water, penetrating through the adhesive edge can be bound by the getter. However, a getter layer in the beam path of an optoelectronic component, for example in the light path, can impair the overall aesthetic appearance of the optoelectronic component and lead to a reduction of that proportion of electromagnetic radiation which can be taken up or provided by the optoelectronic component.

### SUMMARY

In various embodiments, an optoelectronic component and a method for producing an optoelectronic component are provided which make it possible to increase that proportion of electromagnetic radiation which can be taken up or provided by the optoelectronic component with a getter layer.

In the context of this description, an organic substance can be understood to mean a carbon compound which, regardless of the respective state of matter, is present in chemically uniform form and is characterized by characteristic physical and chemical properties. Furthermore, in the context of this description, an inorganic substance can be understood to mean a compound which, regardless of the respective state of matter, is present in chemically uniform form and is characterized by characteristic physical and chemical properties, without carbon or a simple carbon compound. In the context of this description, an organic-inorganic substance (hybrid substance) can be understood to mean a compound which, regardless of the respective state of matter, is present in chemically uniform form and is characterized by characteristic physical and chemical properties, including compound portions which contain carbon and are free of carbon. In the context of this description, the term “substance” encompasses all abovementioned substances, for example an organic substance, an inorganic substance, and/or a hybrid substance. Furthermore, in the context of this description, a substance mixture can be understood to mean something which has constituents consisting of two or more different substances, the constituents of which are very finely dispersed, for example. A substance class should be understood to mean a substance or a substance mixture including one or more organic substance(s), one or more inorganic substance(s) or one or more hybrid substance(s). The term “material” can be used synonymously with the term “substance”.

In the context of this description, a first substance or a first substance mixture can be identical to a second substance or a second substance mixture, respectively, if the chemical and physical properties of the first substance or first substance mixture are identical to the chemical and physical properties of the second substance or of the second substance mixture, respectively.

In the context of this description, a first substance or a first substance mixture can be similar to a second substance or a second substance mixture, respectively, if the first substance or the first substance mixture and the second substance or the second substance mixture, respectively, have an approximately identical stoichiometric composition, approximately identical chemical properties and/or approximately identical physical properties with regard to at least one variable, for example the density, the refractive index, the chemical resistance or the like.

In this respect, by way of example, with regard to the stoichiometric composition crystalline SiO₂ (quartz) can be regarded as identical to amorphous SiO₂ (silica glass) and as similar to SiOₓ. However, with regard to the refractive index, crystalline SiO₂ can be different than SiOₓ or amorphous SiO₂. By the addition of additives, for example in the form of dopings, by way of example, amorphous SiO₂ can have a refractive index which is identical or similar to that of crystalline SiO₂, but can then be different than crystalline SiO₂ with regard to the chemical composition and/or the chemical resistance.

The reference variable in terms of which a first substance is similar to a second substance can be indicated explicitly or become apparent from the context, for example from the common properties of a group of substances or substance mixtures.

In the context of this description, a colorant can be understood to mean a chemical compound or a pigment which can color other substances or substance mixtures, i.e. changes the external appearance of the substance or of the substance mixture.

The term “to color” can also be understood to mean “to change in color” by a colorant, wherein the external color of a substance can be changed in color, without coloring the substance, for example in a manner similar to a color filter. In other words: “changing in color” a substance cannot always comprise “coloring” the substance.

In various configurations, a colorant can may include or be formed from an organic substance from one of the following organic colorant classes: acridine, acridone, squaryllium, spiropyrans, boron-dipyrromethanes (BODIPY), perylenes, pyrenes, naphthalenes, flavins, pyrroles, porphyrins and the metal complexes thereof, diarylmethane, triarylmethane, nitro, nitroso, phthalocyanine and the metal complexes thereof, quinones, azo, indophenol, oxazines, oxazones, thiazines, thiazoles, xanthenes, fluorenes, flurones, pyronines, rhodamines, coumarins, metallocenes.

In various configurations, a colorant can may include or be formed from an inorganic substance from one of the following inorganic colorant class, inorganic colorant derivatives or inorganic colorant pigments: transition metals, rare earth oxides, sulfides, cyanides, iron oxides, zirconium silicates, bismuth vanadate, chromium oxides.

In various configurations, a colorant can may include or be formed from nanoparticles, for example carbon, for example carbon black; gold, silver, platinum.

In the context of this description, phosphor can be understood to mean a substance which converts with losses electromagnetic radiation having one wavelength into electromagnetic radiation having a different wavelength, for example a longer wavelength (Stokes shift) or a shorter wavelength (anti-Stokes shift), for example by phosphorescence or fluorescence. The energy difference between absorbed electromagnetic radiation and emitted electromagnetic radiation can be converted into phonons, i.e. heat, and/or by emission of electromagnetic radiation having a wavelength as a function of the energy difference.

In various configurations, a phosphor may include or be formed from for example Ce³⁺ doped granates such as YAG:Ce and LuAG, for example (Y, Lu)₃(Al,Ga)₅O₁₂:Ce³⁺; Eu²⁺ doped nitrides, for example CaAlSiN₃:Eu²⁺, (Ba,Sr)₂Si₅N₈:Eu²⁺; Eu²⁺ doped sulfides, SIONs, SiAlON, orthosilicates, for example (Ba,Sr,Ca)₂SiO₄: Eu²⁺; chlorosilicates, chlorophosphates, BAM (barium magnesium aluminate:Eu) and/or SCAP, halophosphate.

In the context of this description, a UV-absorbing additive material can reduce the transmission for electromagnetic radiation having a wavelength of less than approximately 400 nm at least in one wavelength range.

The lower UV transmission can be formed for example by a higher absorption and/or reflection and/or scattering of UV radiation by the UV-absorbing additive material.

In various configurations, a UV-absorbing additive material may include or be formed from a substance, a substance mixture or a stoichiometric compound from the group of the following substances: TiO₂, CeO₂, Bi₂O₃, ZnO, SnO₂, a phosphor, UV-absorbing glass particles and/or suitable UV-absorbing metallic nanoparticles, wherein the phosphor, the glass particles and/or the nanoparticles have an absorption of electromagnetic radiation in the UV range.

In various configurations, the UV-absorbing nanoparticles for example can have no or a low solubility in a molten glass solder and/or can react only poorly or not at all with said glass solder.

In various configurations, the nanoparticles can result in no or only little scattering of electromagnetic radiation, for example nanoparticles having a grain size of less than approximately 50 nm, for example composed of TiO₂, CeO₂, ZnO or Bi₂O₃.

A dimensionally stable substance can become plastically formable, i.e. can be liquefied, by the addition of plasticizers, for example solvent, or by the temperature being increased.

A plastically formable substance can become dimensionally stable, i.e. can be solidified, by a crosslinking reaction, withdrawal of plasticizers and/or heat.

Solidifying a substance or substance mixture, i.e. the transition of a substance from formable to dimensionally stable, may include changing the viscosity, for example increasing the viscosity from a first viscosity value to a second viscosity value. The second viscosity value can be greater than the first viscosity value by a multiple, for example in a range of approximately 10 to approximately 10⁶. The substance can be formable at the first viscosity and dimensionally stable at the second viscosity.

Solidifying a substance or substance mixture, i.e. the transition of a substance from formable to dimensionally stable, may include a method or a process in which low molecular weight constituents are removed from the substance or substance mixture, for example solvent molecules or low molecular weight, uncrosslinked constituents of the substance or of the substance mixture, for example drying or chemically crosslinking the substance or the substance mixture. The substance or the substance mixture can have, for example, in the formable state a higher concentration of low molecular weight substances in the overall substance or substance mixture than in the dimensionally stable state.

A body composed of a dimensionally stable substance or substance mixture can be formable, however, for example if the body is designed as a film, for example a plastics film, a glass film or a metal film. Such a body can be referred to as mechanically flexible, for example, since changes in the geometrical shape of the body, for example bending of a film, can be reversible. A mechanically flexible body, for example a film, can also be plastically formable, however, for example by the mechanically flexible body being solidified after the deformation, for example thermoforming of a plastics film.

The connection of a first body to a second body can be positively locking, force locking and/or cohesive. The connections can be embodied as releasable, i.e. reversible. In various configurations, a reversible, cohesive connection can be realized for example as a screw connection, a hook and loop fastener, a clamping/a use of clips.

However, the connections can also be embodied as non-releasable, i.e. irreversible. In this case, a non-releasable connection can be separated only by the connection means being destroyed. In various configurations, an irreversible, cohesive connection can be realized for example as a riveted connection, an adhesively bonded connection or a soldered connection.

In the case of a cohesive connection, the first body can be connected to the second body by atomic and/or molecular forces. Cohesive connections can often be non-releasable connections. In various configurations, a cohesive connection can be realized for example as an adhesively bonded connection, a solder connection, for example of a glass solder, or of a metal solder, a welded connection.

In the context of this description, making electrical contact with an electrical component or an electrical region of the electrical component, for example an electronic component, for example an optoelectronic component, can be understood for example as incorporating the optoelectronic component into an electrical circuit, wherein the circuit can be electrically closed for example by making electrical contact with the electronic component.

In the context of this description, an electronic component can be understood to mean a component which concerns the control, regulation or amplification of an electric current, for example by the use of semiconductor components. An electronic component may include a component from the group of the following components: for example a diode, a transistor, a thermogenerator, an integrated circuits, a thyristor.

In the context of this description, an electronic component with which electrical contact is made can be understood as an embodiment of an electrical component.

In the context of this description, an optoelectronic component can be understood to mean an embodiment of an electronic component, wherein the optoelectronic component includes an optically active region.

In the context of this description, an optically active region of an optoelectronic component can be understood to mean that region of an optoelectronic component which can absorb electromagnetic radiation and form a photocurrent therefrom or can emit electromagnetic radiation by a voltage applied to the optically active region.

In the context of this description, providing electromagnetic radiation can be understood to mean emitting electromagnetic radiation.

In the context of this description, taking up electromagnetic radiation can be understood to mean absorbing electromagnetic radiation.

An optoelectronic component including two planar, optically active sides can be embodied for example as transparent, for example as a transparent organic light emitting diode.

However, the optically active region can also comprise one planar, optically active side and one planar, optically inactive side, for example an organic light emitting diode designed as a top emitter or bottom emitter.

In various configurations, a component which emits electromagnetic radiation can be for example a semiconductor component which emits electromagnetic radiation, and/or can be embodied as a diode which emits electromagnetic radiation, as an organic diode which emits electromagnetic radiation, as a transistor which emits electromagnetic radiation or as an organic transistor which emits electromagnetic radiation. The radiation can be light in the visible range, UV light and/or infrared light, for example. In this connection, the component which emits electromagnetic radiation can be embodied for example as a light emitting diode (LED), as an organic light emitting diode (OLED), as a light emitting transistor or as an organic light emitting transistor. In various configurations, the light emitting component can be part of an integrated circuit. Furthermore, a plurality of light emitting components can be provided, for example in a manner accommodated in a common housing.

In the context of this description, an organic optoelectronic component in various configurations, for example as an organic light emitting diode (OLED), an organic photovoltaic installation, for example an organic solar cell, in the organic functional layer system may include or be formed from an organic substance or an organic substance mixture which is designed for example for providing electromagnetic radiation from an electric current provided or for providing an electric current from electromagnetic radiation provided.

In the context of this description, a harmful environmental influence can be understood to mean all influences which for example can potentially result in degradation, a crosslinked state, and/or crystallization of the organic substance or of the organic substance mixture and can thus limit the operating period of organic components, for example.

A harmful environmental influence can be for example a substance which is harmful to organic substances or organic substance mixtures, for example oxygen and/or for example a solvent, for example water.

A harmful environmental influence can be for example surroundings which are harmful to organic substances or organic substance mixtures, for example a change above or below a critical value, for example of the temperature, and/or a change in the ambient pressure.

In the context of this description, a diffusion channel in a layer can be understood as a cavity in the layer having at least two openings, for example a hole, a pore, an interconnect or the like. A substance or substance mixture can migrate or diffuse through the diffusion channel from one opening of the diffusion channel to the at least one second opening of the diffusion channel, for example by an osmotic pressure or electrophoretically. A diffusion channel can be embodied in the layer for example in such a way that different sides of the layer are connected to one another by the diffusion channel (interconnect). A diffusion channel can have for example a diameter in a range of from approximately the diameter of a water molecule to approximately a few nm. A diffusion channel in a layer can be or be formed by for example defects, grain boundaries or the like in the layer.

In the context of this description, a getter layer may include or be formed from a getter. A getter layer including a getter may include for example a getter in the form of particles which are distributed and/or dissolved in a matrix.

In the context of this description, a “getter” may include a substance or a substance mixture which absorbs harmful substances and/or harmful substance mixtures, for example oxygen or water in the air humidity. However, a getter can also be distributed in a matrix, for example in the form of particles or in a dissolved form, and, by the absorption of harmful substances or harmful substance mixtures, can have the effect that the substance or the substance mixture of the matrix has additional oxygen-repelling and/or moisture-repelling properties.

In the context of this description, a “getter” may include a substance or a substance mixture which absorbs harmful substances and/or harmful substance mixtures, for example oxygen or the water in the air humidity. However, a getter can also be distributed in a matrix, for example in the form of particles or in a dissolved form, and, by the absorption of harmful substances or harmful substance mixtures, can have the effect that the substance or the substance mixture of the matrix has additional oxygen-repelling and/or moisture-repelling properties.

In various configurations, a getter may include or be formed from an oxidizable substance, for example, as substance. An oxidizable substance can for example react with oxygen and/or water and thereby bind these substances. Getters can therefore comprise or be formed from for example readily oxidizing substances from the chemical group of the alkali metal and/or alkaline earth metals, for example magnesium, calcium, barium, cesium, cobalt, yttrium, lanthanum and/or rare earth metals. Furthermore, other metals can also be suitable, for example aluminum, zirconium, tantalum, copper, silver and/or titanium or oxidizable nonmetallic substances. Furthermore, a getter can also comprise or be formed from CaO, BaO and MgO. However, a getter can also comprise or be formed from a drying agent. A drying agent can for example take up water irreversibly, without changing the volume, or bind water by physisorption, without significantly changing its volume in the process.

By the supply of heat, for example by the temperature being increased, the adsorbed water molecules can be removed again. In various configurations, a getter may include or be formed from dried silica gels or zeolites, for example. A getter which includes or is formed from a zeolite can adsorb oxygen and/or water in the pores and channels of the zeolite. Upon the adsorption of water and/or oxygen by dried silica gels and/or zeolites, no harmful substances or substance mixtures can be formed for the underlying layers. Furthermore, the getters composed of dried silica gels and/or zeolite can exhibit no change in the volume by the reaction with water and/or oxygen.

In various configurations, the getter particles can have a mean diameter of less than approximately 50 μm, for example less than approximately 1 μm. In this case, the mean diameter of the getter particles should not be greater than the thickness of the getter layer, for example in order not to damage the adjacent layers and the component.

In various configurations, the getter particles can have for example a maximum mean diameter which corresponds approximately to 20% of the thickness of the getter layer.

Getter particles having a mean diameter of less than approximately 1 μm, for example in a range of approximately 10 nm to approximately 500 nm, can have the advantage that point forces on an OLED, for example, are reduced even in the case of close packing of the getter particles. Furthermore, getter particles having a mean diameter of less than approximately 100 nm can be optically inactive, for example can bring about no scattering of light.

In the context of this description, an antireflection layer can be understood as a layer which is designed for internal coupling-out or internal coupling-in.

Internal coupling-out can involve coupling out for example electromagnetic radiation, for example light, which is guided in the organic functional layer structure of the optoelectronic component, for example the organic functional layer structure and/or the electrodes.

In the context of this description, a mean refractive index of a layer structure having a plurality of partial layers can be understood as an averaged refractive index of the partial layers. The mean refractive index can be the sum of the layer-thickness-averaged refractive indexes of the partial layers. In order to determine a layer-thickness-averaged refractive index of a partial layer, the refractive index of the partial layer can be weighted with the relative proportion of the thickness of the layer structure which is constituted by the thickness of the layer.

In various embodiments, an optoelectronic component is provided, the optoelectronic component including: a carrier; an organic functional layer structure, wherein the organic functional layer structure is embodied on or above a carrier and is designed for taking up and/or providing electromagnetic radiation; an antireflection/getter layer structure arranged in the beam path of the organic functional layer structure and including: getter material having a lower mean refractive index than the organic functional layer structure; and an antireflection layer, wherein material of the antireflection layer is arranged in the beam path of the organic functional layer structure at least partly between the organic functional layer structure and the getter material, and wherein the material of the antireflection layer arranged between the organic functional layer structure and the getter material has a mean refractive index which is greater than the mean refractive index of the getter material and/or includes at least one scattering additive material distributed in a matrix.

In one configuration of the optoelectronic component, the getter can be embodied in a getter layer, wherein the getter is contained in a getter matrix.

In one configuration of the optoelectronic component, the substance or the substance mixture of the getter matrix can be designed for cohesive connection, for example may include or be formed from an adhesive.

In one configuration of the optoelectronic component, at least one type of getter can be designed as at least one type of particles, wherein the at least one type of getter particles is distributed in the getter matrix.

In one configuration of the optoelectronic component, at least one type of getter can be dissolved in the getter matrix.

In one configuration of the optoelectronic component, at least one type of getter can be embodied in such a way that the getter reacts with at least one harmful substance.

In one configuration of the optoelectronic component, the getter may include or be formed from a substance such that the at least one harmful substance reacts chemically with the getter.

In one configuration of the optoelectronic component, the getter may include or be formed from a substance such that the at least one harmful substance is physisorbed at the getter.

In one configuration of the optoelectronic component, the organic functional layer structure, the getter layer and/or the antireflection layer can be embodied as translucent and/or transparent.

In one configuration of the optoelectronic component, the optoelectronic component can be embodied as an organic, optoelectronic component, for example an organic solar cell or an organic light emitting diode.

In one configuration of the optoelectronic component, the organic functional layer structure the optoelectronic component can furthermore comprise a first electrode and a second electrode, wherein the organic functional layer structure is arranged electrically between the electrodes.

In one configuration of the optoelectronic component, the optoelectronic component can furthermore comprise at least one barrier thin-film layer between the organic functional layer structure and the getter.

In one configuration of the optoelectronic component, the at least one barrier thin-film layer can be embodied in such a way that the organic functional layer structure is protected against harmful substances, for example by virtue of the barrier thin-film layer being embodied in physical contact with the organic functional layer structure and surrounding this.

In one configuration of the optoelectronic component, the at least one barrier thin-film layer may include or be formed from a substance which is intrinsically impermeable with regard to harmful substances with regard to the organic functional layer structure, for example impermeable with regard to water and/or oxygen.

In one configuration of the optoelectronic component, the at least one barrier thin-film layer may include or be formed from a ceramic, a metal and/or a metal oxide.

In one configuration of the optoelectronic component, the at least one barrier thin-film layer can at least partly surround the organic functional layer structure, for example at least partly from below, at least partly laterally and/or at least partly from above, for example completely.

In one configuration of the optoelectronic component, the at least one barrier thin-film layer can laterally and/or areally surround the organic functional layer structure.

In one configuration of the optoelectronic component, the at least one barrier thin-film layer together with the carrier can completely surround the organic functional layer structure.

In one configuration of the optoelectronic component, the barrier thin-film layer can have diffusion channels with regard to at least one harmful substance of the organic functional layer structure, wherein the diffusion channels penetrate through the barrier thin-film layer.

In one configuration of the optoelectronic component, the optoelectronic component may include an optically active region and an optically inactive region.

In one configuration of the optoelectronic component, at least the optically inactive region may include a getter, for example a getter layer.

In one configuration of the optoelectronic component, the getter layer can have a first thickness in a first region and a second thickness in a second region, wherein the second thickness is less than the first thickness. The transition between the first region and the second region can for example be discontinuous, for example in a manner similar to a step, or be embodied as continuous, for example linear, nonlinear.

In one configuration of the optoelectronic component, the first region can have the optically active region and the second region can have the optically inactive region.

In one configuration of the optoelectronic component, the antireflection layer can be embodied in such a way that the proportion of the electromagnetic radiation which is reflected by at least one interface of the getter layer is reduced.

In one configuration of the optoelectronic component, the antireflection layer can have a higher refractive index than the getter layer.

In one configuration of the optoelectronic component, the antireflection layer can have a higher mean refractive index than the organic functional layer structure.

In one configuration of the optoelectronic component, the antireflection layer can be embodied in the beam path of the optoelectronic component between the organic functional layer structure and the getter layer.

In one configuration of the optoelectronic component, the antireflection layer can have a mean refractive index in a range of approximately 1.5 to approximately 2.5.

In one configuration of the optoelectronic component, the antireflection layer may include at least one type of additives in a matrix. The substance or the substance mixture of the matrix can also be referred to as molding material or potting material.

In one configuration of the optoelectronic component, the matrix may include a substance or a substance mixture which intrinsically has a refractive index in a range of approximately 1.3 to approximately 2.5.

In one configuration of the optoelectronic component, at least one type of additive material of the antireflection layer of the antireflection layer can be embodied in such a way that the antireflection layer has a mean refractive index in a range of approximately 1.5 to approximately 2.5.

In one configuration of the method, a type of additive material which increases the refractive index of the antireflection layer can be embodied as particles. The particles can be embodied for example as non-scattering for light, for example can have a mean diameter in a range of approximately 10 nm to approximately 200 nm. The particles can have for example a refractive index in a range of approximately 1.5 to approximately 2.5. This type of additive material may include or be formed from—as substance or substance mixture—for example a metal, a metal oxide, and/or a ceramic, for example TiO₂, Al₂O₃, Y₂O₃ or ZrO₂. This type of additive material can have for example a proportion by mass with regard to the antireflection layer in a range of approximately 2% to approximately 70%.

In one configuration of the optoelectronic component, the antireflection layer may include at least one type of additive material.

In one configuration of the optoelectronic component, the getter can be embodied as a type of additive material of the antireflection layer.

In one configuration of the optoelectronic component, at least one type of additive material can be embodied as particles, i.e. particulate additives.

In one configuration of the optoelectronic component, at least one type of additive material can be dissolved in the matrix.

In one configuration of the optoelectronic component, the matrix may include or be formed from a glass solder and/or a plastic.

In one configuration of the optoelectronic component, the antireflection layer can be embodied, for example arranged, in a planar fashion, for example over the whole area, on or above the substrate.

In one configuration of the optoelectronic component, the antireflection layer can have a thickness in a range of approximately 1 μm to approximately 100 μm, for example in a range of approximately 10 μm to approximately 100 μm, for example approximately 25 μm.

In one configuration of the optoelectronic component, the antireflection layer can be embodied as a layer in a sectional plane of an organic light emitting diode and/or an organic solar cell.

In one configuration of the optoelectronic component, the matrix of the antireflection layer can be embodied in an amorphous fashion.

In one configuration of the optoelectronic component, the matrix of the antireflection layer may include a glass and/or a plastic.

In one configuration of the optoelectronic component, the matrix of the antireflection layer may include or be formed from a substance or substance mixture from the group of the following glass systems: PbO-containing systems: PbO—B₂O₃, PbO—SiO₂, PbO—B₂O₃—SiO₂, PbO—B₂O₃—ZnO₂, PbO—B₂O₃—Al₂O₃, wherein the PbO-containing glass solder can also comprise Bi₂O₃; Bi₂O₃-containing systems: Bi₂O₃—B₂O₃, Bi₂O₃—B₂O₃—SiO₂, Bi₂O₃—B₂O₃—ZnO, Bi₂O₃—B₂O₃—ZnO—SiO₂.

In one configuration of the optoelectronic component, the Bi-containing antireflection layer can additionally comprise a substance or a substance mixture from the group of the following substances: Al₂O₃, alkaline earth metal oxides, alkali metal oxides, ZrO₂, TiO₂, HfO₂, Nb₂O₅, Ta₂O₅, TeO₂, WO₃, MO₃, Sb₂O₃, Ag₂O, SnO₂, rare earth oxides.

In one configuration of the optoelectronic component, the glass of the matrix can be admixed with UV-absorbing additives as glass components. By way of example, substances or substance mixtures including Ce, Fe, Sn, Ti, Pr, Eu and/or V compounds can be added as glass batch constituents to glasses having a low melting point, for example lead-containing glasses, in order to increase the UV absorption, in the glass melt process.

The glass melting process can be understood to mean thermal liquefaction, i.e. melting, of a glass. The UV-absorbing additives can be dissolved in the glass as constituents. After the glass melting process, the glass can be powdered, applied to a carrier in the form of coatings and then be vitrified by a thermal treatment.

In one configuration of the optoelectronic component, the substance or the substance mixture of the matrix can have an intrinsically lower UV transmission than the substrate.

By the lower UV transmission of the matrix, it is possible to form UV protection for layers with regard to the beam path on or above the antireflection layer.

The lower UV transmission of the matrix of the antireflection layer with regard to the substrate can be formed for example by a higher absorption and/or reflection of UV radiation.

In one configuration of the optoelectronic component, the substance or the substance mixture of the matrix of the antireflection layer can be liquefied at a temperature of up to a maximum of approximately 600° C.

In one configuration of the optoelectronic component, the matrix may include or be formed from one of the following substances: a silicone, for example polydimethylsiloxane, polydimethylsiloxane/poly-diphenylsiloxane; a silazane, an epoxide, a polyacrylate, a polycarbonate, a polyimide, a polyurethane or the like, for example a silicone hybrid, a silicone-epoxide hybrid.

In one configuration of the optoelectronic component, the additives may include or be formed from an inorganic substance or an inorganic substance mixture.

In one configuration of the optoelectronic component, the at least one type of additive material of the antireflection layer may include or be formed from a substance, a substance mixture or a stoichiometric compound from the group of the following substances: TiO₂, CeO₂, Bi₂O₃, ZnO, SnO₂, Al₂O₃, SiO₂, Y₂O₃, ZrO₂, a phosphor, a colorant, a UV-absorbing additive material, for example UV-absorbing glass particles, UV-absorbing metallic nanoparticles, a UV-absorbing phosphor.

In one configuration of the optoelectronic component, the additives can have a curved surface, for example in a manner similar or identical to an optical lens, for example in a manner similar to a converging lens or diverging lens.

In one configuration of the optoelectronic component, the particulate additives can have one of the following geometrical shapes and/or a part of one of the following geometrical shapes: spherical, aspherical, for example prismatic, ellipsoid, hollow, for example percolation-shaped; compact, laminar, rod-shaped or thread-like.

In one configuration of the optoelectronic component, the particulate additives may include or be formed from a glass.

In one configuration of the optoelectronic component, the particulate additives can have an average grain size in a range of approximately 0.01 μm to approximately 10 μm, for example in a range of approximately 0.1 μm to approximately 1 μm.

In one configuration of the optoelectronic component, the additives on or above the substrate in the antireflection layer can have one ply having a thickness of approximately 0.1 μm to approximately 100 μm.

In one configuration of the optoelectronic component, the additives of the antireflection layer can have a plurality of plies one above another on or above the substrate, wherein the individual plies can be embodied differently.

In one configuration of the optoelectronic component, in the plies of the additives, the average size of the particulate additives of at least one particulate additive material can decrease from the surface of the substrate.

In one configuration of the optoelectronic component, the individual plies of the additives can have a different average size of the particulate additives and/or a different optical property for electromagnetic radiation in at least one wavelength range, for example with a wavelength of less than approximately 400 nm.

In one configuration of the optoelectronic component, the individual plies of the additives can have a different average size of the particulate additives and/or a different refractive index for electromagnetic radiation.

In one configuration of the optoelectronic component, the antireflection layer can be designed as a scattering layer, i.e. as a coupling-out or coupling-in layer.

In one configuration of the optoelectronic component, the antireflection layer may include particulate additives which are designed as scattering particles for electromagnetic radiation, for example light, wherein the scattering particles can be distributed in the matrix.

In other words: the matrix may include at least one scattering additive material, such that the antireflection layer can additionally form a scattering effect with regard to incident electromagnetic radiation in at least one wavelength range, for example by a refractive index of the scattering particles or scattering additives that is different relative to the matrix, and/or a diameter corresponding approximately to the magnitude of the wavelength of the radiation to be scattered.

The scattering effect can concern electromagnetic radiation which is emitted or absorbed by the organic functional layer system, for example in order to increase the coupling-out of light or coupling-in of light.

In one configuration of the optoelectronic component, the antireflection layer including scattering additives can have a difference between the refractive index of the scattering additives and the refractive index of the matrix of greater than approximately 0.05.

In one configuration of the optoelectronic component, the part of the scattering layer above the scattering centers can have a thickness greater than or equal to the roughness of the topmost ply of the scattering particles without a matrix, such that at least one smooth surface is formed, i.e. the surface can have a low RMS roughness (root mean square−absolute value of the mean deviation), for example less than 10 nm.

In one configuration of the optoelectronic component, an additive material can be designed as a colorant.

In one configuration of the optoelectronic component, the optical appearance of the antireflection layer can be varied by the colorant.

In one configuration of the optoelectronic component, the colorant can absorb electromagnetic radiation in an application-specifically non-relevant wavelength range or undesired wavelength ranges, for example greater than approximately 700 nm. As a result, the optical appearance of the antireflection layer can be varied, for example the antireflection layer being colored without the efficiency being impaired in a wavelength range technically relevant to the application of the optoelectronic component. In other words: in one configuration, the antireflection layer can additionally be designed as a color layer.

In one configuration of the optoelectronic component, an additive material of the antireflection layer can be designed as a type of UV-absorbing additive material.

In other words: in one configuration, the antireflection layer can additionally be designed as a UV protection layer.

In one configuration of the optoelectronic component, an additive material of the antireflection layer can be embodied as wavelength-converting additive material, for example as a phosphor.

In other words: in one configuration, the antireflection layer can additionally be designed as a phosphor layer.

In one configuration of the optoelectronic component, an additive material of the antireflection layer can be designed as a getter.

In other words: in one configuration, the antireflection layer can additionally be designed as a getter layer.

In one configuration of the optoelectronic component, the additives can scatter electromagnetic radiation, absorb UV radiation, convert the wavelength of electromagnetic radiation, color the antireflection layer and/or bind harmful substances.

Additives which for example can scatter electromagnetic radiation and can absorb no UV radiation may include or be formed from Al₂O₃, SiO₂, Y₂O₃ or ZrO₂, for example.

Additives which for example scatter electromagnetic radiation and convert the wavelength of electromagnetic radiation can be designed for example as glass particles with a phosphor.

In one configuration of the optoelectronic component, the getter particles can be designed as scattering particles.

In one configuration of the optoelectronic component, the antireflection layer can be structured, for example topographically, for example laterally and/or vertically; for example by a different substance composition of the antireflection layer, for example laterally and/or vertically, for example with a different local concentration of at least one additive material.

In one configuration of the optoelectronic component, the concentration of the additives in the antireflection layer in at least one third region can be less or greater than in a fourth region.

In one configuration of the optoelectronic component, the antireflection layer can have at least one structured interface. The at least one structured interface can be formed for example by roughening one of the interfaces or forming a pattern at one of the interface of the antireflection layer.

In one configuration of the optoelectronic component, the structured interface of the antireflection layer can be formed by microlenses.

The microlenses and/or the interfacial roughness can be understood for example as scattering centers, for example for increasing the coupling-in of light/coupling-out of light.

In one configuration of the optoelectronic component, the antireflection layer can be embodied as an optical grating, wherein the optical grating has a structured layer having regions having a low refractive index.

In one configuration of the optoelectronic component, at least one antireflection layer together with the carrier can at least partly surround the organic functional layer structure, for example at least partly from below, at least partly laterally and/or at least partly from above, for example completely.

In one configuration of the optoelectronic component, the at least one getter layer together with the carrier can at least partly surround the organic functional layer structure, the at least one barrier thin-film layer and/or the at least one antireflection layer, for example at least partly from below, at least partly laterally and/or at least partly from above, for example completely.

In one configuration of the optoelectronic component, the optoelectronic component can furthermore comprise at least one protective layer on or above the antireflection layer, wherein the protective layer is embodied in such a way that the antireflection layer is protected against at least one harmful substance.

In one configuration of the optoelectronic component, the at least one protective layer can at least partly surround the organic functional layer structure, the at least one barrier thin-film layer, the at least one antireflection layer and/or the at least one getter layer, for example at least partly from below, at least partly laterally and/or at least partly from above, for example completely.

In one configuration of the optoelectronic component, the optoelectronic component can furthermore comprise a cover on or above the getter, wherein the cover is arranged in such a way that the diffusion rate of at least one harmful substance into the getter is reduced, for example on or above a planar surface of the optoelectronic component.

In one configuration of the optoelectronic component, the organic functional layer structure can be arranged on or above the getter and/or the barrier thin-film layer.

In one configuration of the optoelectronic component, at least one electrical feedthrough can be formed in the at least one protective layer, the carrier, the at least one barrier thin-film layer, the at least one antireflection layer and/or the at least one getter layer, wherein the electrical feedthrough is designed for making electrical contact with the organic functional layer structure, for example for making electrical contact with the at least one electrode which is electrically connected to the organic functional layer structure.

In one configuration of the optoelectronic component, the optoelectronic component may include at least two antireflection/getter layer structures, wherein the at least two antireflection/getter layer structures are arranged on or above the same side or on or above different sides of the organic functional layer structure.

In various embodiments, a method for producing an optoelectronic component is provided, the method including: providing an organic functional layer structure on or above a carrier, wherein the organic functional layer structure is embodied for taking up and/or providing electromagnetic radiation; forming an antireflection/getter layer structure in the beam path of the organic functional layer structure, the antireflection/getter layer structure including: a getter material having a lower mean refractive index than the organic functional layer structure; and an antireflection layer, wherein material of the antireflection layer is formed in the beam path of the organic functional layer structure at least partly between the organic functional layer structure and the getter material, and wherein the material of the antireflection layer arranged between the organic functional layer structure and the getter material has a mean refractive index which is greater than the mean refractive index of the getter material and/or includes at least one scattering additive material distributed in a matrix.

In one configuration of the method, the organic functional layer structure, the getter layer and/or the antireflection layer can be embodied as translucent and/or transparent.

In one configuration of the method, the optoelectronic component can be embodied as an organic, optoelectronic component, for example an organic solar cell or an organic light emitting diode.

In one configuration of the method, the method can furthermore comprise forming a first electrode and a second electrode, wherein the organic functional layer structure is formed electrically between the electrodes.

In one configuration of the method, the getter can be embodied in a getter layer, wherein the getter is contained in a getter matrix.

In one configuration of the method, the substance or the substance mixture of the getter matrix can be designed for cohesive connection, for example may include or be formed from an adhesive.

In one configuration of the method, at least one type of getter can be designed as at least one type of particles, wherein the at least one type of getter particles is distributed in the getter matrix, for example homogeneously and/or as at least one ply.

In one configuration of the method, at least one type of getter can be dissolved in the getter matrix.

In one configuration of the method, at least one type of getter can be embodied in such a way that the getter reacts with the at least one harmful substance.

In one configuration of the method, the getter may include or be formed from a substance such that the at least one harmful substance reacts chemically with the getter.

In one configuration of the method, the getter may include or be formed from a substance such that the at least one harmful substance is physisorbed at the getter.

In one configuration of the method, the method can furthermore forming an optically active region and an optically inactive region wherein a getter, for example a getter layer, is formed at least in the optically inactive region.

In one configuration of the method, the getter layer can be formed with a first thickness in a first region and with a second thickness in a second region, wherein the second thickness is less than the first thickness. The transition between the first region and the second region can for example be discontinuous, for example in a manner similar to a step, or be embodied as continuous, for example linear, nonlinear.

In one configuration of the method, the first region can have the optically active region and the second region can have the optically inactive region.

In one configuration of the method, the method can furthermore comprise forming at least one barrier thin-film layer between the organic functional layer structure and the getter, for example in physical contact with the organic functional layer structure.

In one configuration of the method, the at least one barrier thin-film layer can be formed in such a way that the organic functional layer structure is protected against harmful substances.

In one configuration of the method, the at least one barrier thin-film layer may include or be formed from a substance which is intrinsically impermeable with regard to harmful substances, for example impermeable with regard to water and/or oxygen.

In one configuration of the method, the at least one barrier thin-film layer may include or be formed from a ceramic, a metal and/or a metal oxide.

In one configuration of the method, the at least one barrier thin-film layer can be formed in such a way that the at least one barrier thin-film layer at least partly surrounds the organic functional layer structure, for example at least partly from below, at least partly laterally and/or at least partly from above, for example completely.

In one configuration of the method, the at least one barrier thin-film layer can be formed in such a way that the at least one barrier thin-film layer laterally and/or areally surrounds the organic functional layer structure.

In one configuration of the method, the at least one barrier thin-film layer can be formed in such a way that the at least one barrier thin-film layer together with the carrier completely surrounds the organic functional layer structure.

In one configuration of the method, the barrier thin-film layer can have diffusion channels with regard to at least one harmful substance of the organic functional layer structure, wherein the diffusion channels penetrate through the barrier thin-film layer.

In one configuration of the method, the antireflection layer can be embodied in such a way that the proportion of the electromagnetic radiation which is reflected by at least one interface of the getter layer is reduced.

In one configuration of the method, the antireflection layer can be formed in such a way that the antireflection layer has a higher mean refractive index than the organic functional layer structure.

In one configuration of the method, the antireflection layer can be embodied in the beam path of the optoelectronic component between the organic functional layer structure and the getter layer.

In one configuration of the method, the antireflection layer can be formed in such a way that the antireflection layer has approximately a mean refractive index between the absolute value of the mean refractive index of the organic functional layer structure and the absolute value of the mean refractive index of the getter layer.

In one configuration of the method, the antireflection layer can be formed in such a way that the antireflection layer has a mean refractive index in a range of approximately 1.5 to approximately 2.5.

In one configuration of the method, the antireflection layer can be formed in such a way that the antireflection layer includes at least one type of additive material in a matrix. The substance or the substance mixture of the matrix can also be referred to as molding material or potting material.

In one configuration of the method, at least one type of additive material can be distributed in the matrix.

In one configuration of the method, at least one type of additive material can be embodied as particles, i.e. particulate additives.

In one configuration of the method, at least one type of additive material can be dissolved in the matrix.

In one configuration of the method, the matrix may include a substance or a substance mixture which intrinsically has a refractive index in a range of approximately 1.3 to approximately 2.5.

In one configuration of the method, at least one type of additive material of the antireflection layer can be embodied in such a way that the antireflection layer has a mean refractive index in a range of approximately 1.5 to approximately 2.5.

In one configuration of the method, a type of additive material which increases the refractive index of the antireflection layer can be embodied as particles. The particles can be embodied for example as non-scattering for light, for example can have a mean diameter in a range of approximately 10 nm to approximately 200 nm. The particles can have for example a refractive index in a range of approximately 1.5 to approximately 2.5. This type of additive material may include or be formed from—as substance or substance mixture—for example a metal, a metal oxide, and/or a ceramic, for example TiO₂, Al₂O₃, Y₂O₃ or ZrO₂. This type of additive material can have for example a proportion by mass with regard to the antireflection layer in a range of approximately 2% to approximately 70%.

In one configuration of the method, the getter can be embodied as a type of additive material of the antireflection layer.

In one configuration of the method, the matrix may include or be formed from a glass solder and/or a plastic.

In one configuration of the method, the antireflection layer can be embodied, for example arranged, over the whole area, on or above the substrate.

In one configuration of the method, the antireflection layer can be embodied with a thickness in a range of approximately 1 μm to approximately 100 μm, for example in a range of approximately 10 μm to approximately 100 μm, for example approximately 25 μm.

In one configuration of the method, the matrix of the antireflection layer can be embodied in an amorphous fashion.

In one configuration of the method, the matrix of the antireflection layer may include or be formed from one of the substances from the following group of the glass systems: PbO-containing systems: PbO—B₂O₃, PbO—SiO₂, PbO—B₂O₃—SiO₂, PbO—B₂O₃—ZnO₂, PbO—B₂O₃—Al₂O₃, wherein the PbO-containing glass solder can also comprise Bi₂O₃; Bi₂O₃-containing systems: Bi₂O₃—B₂O₃, Bi₂O₃—B₂O₃—SiO₂, Bi₂O₃—B₂O₃—ZnO, Bi₂O₃—B₂O₃—ZnO—SiO₂.

In one configuration of the method, the Bi-containing antireflection layer can additionally comprise one of the following substances or a substance mixture from the following substances: Al₂O₃, alkaline earth metal oxides, alkali metal oxides, ZrO₂, TiO₂, HfO₂, Nb₂O₅, Ta₂O₅, TeO₂, WO₃, MO₃, Sb₂O₃, Ag₂O, SnO₂, rare earth oxides.

In one configuration of the method, the glass of the matrix can be admixed with additives, for example UV-absorbing additives, as glass components.

By way of example, substances or substance mixtures including Ce, Fe, Sn, Ti, Pr, Eu and/or V compounds can be added as glass batch constituents to glasses having a low melting point, for example lead-containing glasses, in order to increase the UV absorption, in the glass melt process.

The glass melting process can be understood to mean thermal liquefaction, i.e. melting, of a glass.

Additives, for example UV-absorbing additives, can be dissolved in the glass for example as constituents.

After the glass melting process, the glass can be powdered to form glass particles, applied to a carrier in the form of coatings and then be vitrified by a thermal treatment.

In one configuration of the method, the substance or the substance mixture of the matrix can have an intrinsically lower UV transmission than the substrate.

By the lower UV transmission of the matrix, it is possible to form UV protection for layers on or above the antireflection layer. The lower UV transmission of the matrix of the antireflection layer with regard to the substrate can be formed for example by a higher absorption and/or reflection of UV radiation.

In one configuration of the method, the substance or the substance mixture of the matrix of the antireflection layer can be liquefied at a temperature of up to a maximum of approximately 600° C.

In one configuration of the method, the substance or the substance mixture of the matrix can be formed as glass particles before the antireflection layer is formed.

In one configuration of the method, the glass particles may include additives, for example the particulate additives.

In one configuration of the method, from the at least one type of additives a ply of particulate additives can be formed on or above the substrate.

In one configuration of the method, a coating composed of glass particles can be formed on or above a ply of particulate additives. The formation of the coating composed of glass particles can be formed for example by a glass particle suspension or glass particle paste.

In one configuration of the method, the glass particle suspension or glass particle paste on or above the particulate additives can be dried by evaporating constituents at a first temperature.

In one configuration of the method, by increasing the temperature, it is possible to substantially completely remove the organic constituents (binder) from the dried layer of the particulate additives and from the dried glass powder layer.

In one configuration of the method, by increasing the temperature to a second value, wherein the second temperature is very much greater than the first temperature of drying, it is possible to soften the glass or glass powder of the substance or of the substance mixture of the matrix of the antireflection layer in such a way that it is liquefied, for example can flow.

The maximum magnitude of the second temperature value for liquefying or vitrifying the glass powder layer can be dependent on the carrier of the optoelectronic component. The temperature regime (temperature and time) can be chosen in such a way that the carrier is not deformed, but the glass solder of the antireflection layer already has a viscosity such that it can run smoothly, i.e. can flow, and a very smooth vitreous surface can be formed.

The glass of the glass powder layer can have a second temperature, i.e. the vitrification temperature, for example below the transformation point of the carrier, for example of the carrier glass (viscosity of the carrier η=10^{14.5} dPa·s), and maximally at the softening temperature (viscosity of the carrier η=10^{7.6} dPa·*s) of the carrier glass, for example below the softening temperature and approximately at the upper cooling point (viscosity of the carrier η=10^{13.0} dPa·s).

In one configuration of the method, the glass powder, with the use of a soda-lime glass as carrier, can be vitrified at temperatures of up to a maximum of approximately 600° C.

In one configuration of the method, by the liquefied glass of the substance or of the substance mixture of the matrix of the antireflection layer which flows between the particulate additives, it is possible to form at least one uninterrupted continuous glass connection of the carrier to the liquefied glass above the particulate additives.

In one configuration of the method, the surface of the liquefied glass above the particulate additives, after solidification of the glass, can be additionally smoothed again by local heating.

In one configuration of the method, the local heating can be formed by plasma or laser radiation.

In one configuration of the method, the matrix of the antireflection layer may include or be formed from one of the following substances: a silicone, for example polydimethylsiloxane, polydimethylsiloxane/poly-diphenylsiloxane; a silazane, an epoxide, a polyacrylate, a polycarbonate, a polyimide, a polyurethane or the like, for example a silicone hybrid, a silicone-epoxide hybrid.

In one configuration of the method, the antireflection layer can be formed wet-chemically, for example from a solution, suspension, dispersion or paste.

In one configuration of the method, the additives can be dissolved in the solution, suspension, dispersion or paste of the organic matrix.

In one configuration of the method, the organic matrix can be applied on or above a ply of particulate additives in such a way that the substance or the substance mixture dissolves the additives or runs between the particulate additives.

In one configuration, the antireflection layer can be formed by blade coating of a solution, paste, suspension or dispersion.

In one configuration of the method, the additives may include or be formed from an inorganic substance or an inorganic substance mixture.

In one configuration of the method, the at least one type of additive material of the antireflection layer may include or be formed from a substance or a substance mixture or a stoichiometric compound from the group of the following substances: TiO₂, CeO₂, Bi₂O₃, ZnO, SnO₂, Al₂O₃, SiO₂, Y₂O₃, ZrO₂, a phosphor, a colorant, a UV-absorbing additive material, for example UV-absorbing glass particles, UV-absorbing metallic nanoparticles, a UV-absorbing phosphor.

In one configuration of the method, the additives can have a curved surface, for example in a manner similar or identical to an optical lens.

In one configuration of the method, the particulate additives can have one of the following geometrical shapes and/or a part of one of the following geometrical shapes: spherical, aspherical, for example prismatic, ellipsoid, hollow, for example percolation-shaped; compact, laminar, rod-shaped or thread-like.

In one configuration of the method, the particulate additives may include or be formed from a glass.

In one configuration of the method, the particulate additives can have an average grain size in a range of approximately 0.01 μm to approximately 10 μm, for example in a range of approximately 0.1 μm to approximately 1 μm.

In one configuration of the method, the additives on or above the substrate in the antireflection layer can have one ply having a thickness of approximately 0.1 μm to approximately 100 μm.

In one configuration of the method, the additives of the antireflection layer can have a plurality of plies one above another on or above the substrate, wherein the individual plies can be embodied differently.

In one configuration of the method, in the plies of the additives, the average size of the particulate additives of at least one particulate additive material can decrease from the surface of the substrate.

In one configuration of the method, the individual plies of the additives can have a different average size of the particulate additives and/or a different transmission for electromagnetic radiation in at least one wavelength range, for example with a wavelength of less than approximately 400 nm.

In one configuration of the method, the individual plies of the additives can have a different average size of the particulate additives and/or a different refractive index for electromagnetic radiation.

In one configuration of the method, the antireflection layer can be embodied as a scattering layer, i.e. as a coupling-out layer or coupling-in layer.

In one configuration of the method, the antireflection layer may include particulate additives which are designed as scattering particles for electromagnetic radiation, for example light, wherein the scattering particles can be distributed in the matrix.

In other words: the matrix may include at least one scattering additive material, such that the antireflection layer can additionally form a scattering effect with regard to incident electromagnetic radiation in at least one wavelength range, for example by a refractive index of the scattering particles or scattering additives that is different relative to the matrix, and/or a diameter corresponding approximately to the magnitude of the wavelength of the radiation to be scattered.

The scattering effect can concern electromagnetic radiation which is emitted or absorbed by the organic functional layer system, for example in order to increase the coupling-out of light or coupling-in of light.

In one configuration of the method, the antireflection layer can be formed in such a way that the antireflection layer including scattering additives has a difference between the refractive index of the scattering additives and the refractive index of the matrix of greater than approximately 0.05.

In one configuration of the method, the antireflection layer can be formed in such a way that the part of the antireflection layer above the scattering centers has a thickness greater than or equal to the roughness of the topmost ply of the scattering particles without a matrix, such that at least one smooth surface is formed, i.e. the surface can have a low RMS roughness (root mean square−absolute value of the mean deviation), for example less than 10 nm.

In one configuration of the method, an additive material can be designed as a colorant.

In one configuration of the method, the optical appearance of the antireflection layer and/or of the optoelectronic component can be varied by the colorant.

In one configuration of the method, the colorant can absorb electromagnetic radiation in an application-specifically non-relevant wavelength range or undesired wavelength ranges, for example greater than approximately 700 nm. As a result, the optical appearance of the antireflection layer can be varied, for example the antireflection layer being colored without the efficiency being impaired in a wavelength range technically relevant to the application of the optoelectronic component. In other words: in one configuration, the antireflection layer can additionally be designed as a color layer.

In one configuration of the method, an additive material of the antireflection layer can be designed as a type of UV-absorbing additive material.

In other words: in one configuration, the antireflection layer can additionally be designed as a UV protection layer.

In one configuration of the method, an additive material of the antireflection layer can be embodied as wavelength-converting additive material, for example as a phosphor.

In other words: in one configuration, the antireflection layer can additionally be designed as a phosphor layer.

In one configuration of the method, an additive material of the antireflection layer can be designed as a getter.

In other words: in one configuration, the antireflection layer can additionally be designed as a getter layer.

In one configuration of the method, the additives can scatter electromagnetic radiation, absorb UV radiation, convert the wavelength of electromagnetic radiation, color the antireflection layer and/or bind harmful substances.

Additives which for example can scatter electromagnetic radiation and can absorb no UV radiation may include or be formed from Al₂O₃, SiO₂, Y₂O₃ or ZrO₂, for example.

Additives which for example scatter electromagnetic radiation and convert the wavelength of electromagnetic radiation can be designed for example as glass particles with a phosphor.

In one configuration of the method, the getter particles can be designed as scattering particles.

In one configuration of the method, the antireflection layer can be structured, for example topographically, for example laterally and/or vertically; for example by a different substance composition of the antireflection layer, for example laterally and/or vertically, for example with a different local concentration of at least one additive material.

In one configuration of the method, the concentration of the additives in the antireflection layer in at least one third region of the optoelectronic component can be less or greater than in a fourth region, for example in the optically inactive region.

In one configuration of the method, the antireflection layer can be formed with at least one structured interface.

The at least one structured interface can be formed for example by roughening one of the interfaces or forming a pattern at one of the interface of the antireflection layer.

In one configuration of the method, the structured interface of the antireflection layer can be formed by microlenses.

The microlenses and/or the interfacial roughness can be understood for example as scattering centers, for example for increasing the coupling-in of light/coupling-out of light.

In one configuration of the method, the antireflection layer can be embodied as an optical grating, wherein the optical grating has a structured layer having regions having a low refractive index.

In one configuration of the method, the at least one antireflection layer can be formed in such a way that the at least one antireflection layer at least partly surrounds the organic functional layer structure, for example at least partly from below, at least partly laterally and/or at least partly from above, for example completely.

In one configuration of the method, the at least one getter layer can be formed in such a way that the at least one getter layer at least partly surrounds the organic functional layer structure, the at least one barrier thin-film layer and/or the at least one antireflection layer, for example at least partly from below, at least partly laterally and/or at least partly from above, for example completely.

In one configuration of the method, the method can furthermore comprise forming at least one protective layer on or above the antireflection layer, wherein the protective layer is embodied in such a way that the antireflection layer is protected against at least one harmful substance.

In one configuration of the method, the at least one protective layer can be formed in such a way that the at least one protective layer at least partly surrounds the organic functional layer structure, the at least one barrier thin-film layer, the at least one antireflection layer and/or the at least one getter layer, for example at least partly from below, at least partly laterally and/or at least partly from above, for example completely.

In one configuration of the method, the method can furthermore comprise forming a cover on or above the getter, wherein the cover is arranged and/or formed in such a way that the diffusion rate of at least one harmful substance into the getter is reduced, for example on or above a planar surface of the optoelectronic component.

In one configuration of the method, the organic functional layer structure can be formed on or above the getter and/or the barrier thin-film layer.

In one configuration of the method, at least one electrical feedthrough can be formed in the at least one protective layer, the carrier, the barrier thin-film layer, the at least one antireflection layer and/or the getter layer, wherein the electrical feedthrough is designed for making electrical contact with the organic functional layer structure, for example for making electrical contact with the at least one electrode of the organic functional layer structure.

In one configuration of the method, the optoelectronic component can be formed with at least two antireflection/getter layer structures, wherein the at least two antireflection/getter layer structures are formed on or above the same side or on or above different sides of the organic functional layer structure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic cross-sectional view of an optoelectronic component, in accordance with various embodiments;

FIGS. 2A and 2B show schematic cross-sectional views of optoelectronic components, in accordance with various configurations;

FIGS. 3A and 3B show schematic cross-sectional views of optoelectronic components, in accordance with various configurations;

FIGS. 4A to 4D show schematic cross-sectional views of optoelectronic components, in accordance with various configurations;

FIGS. 5A to 5C show schematic cross-sectional views of optoelectronic components, in accordance with various configurations; and

FIGS. 6A and 6B show different configurations of a conventional optoelectronic component.

### DETAILED DESCRIPTION

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

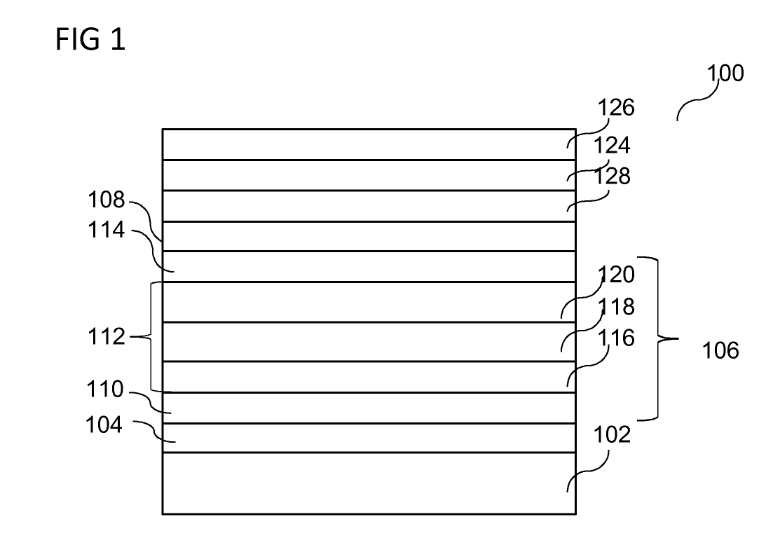

FIG. 1 shows a schematic cross-sectional view of an optoelectronic component, in accordance with various embodiments.

The optoelectronic component 100, for example an electronic component 100 which provides electromagnetic radiation, for example a light emitting component 100, for example in the form of an organic light emitting diode 100, can have a carrier 102. The carrier 102 can serve for example as a carrier element for electronic elements or layers, for example light emitting elements. By way of example, the carrier 102 may include or be formed from glass, quartz and/or a semiconductor material or any other suitable substance. Furthermore, the carrier 102 may include or be formed from a plastics film or a laminate including one or including a plurality of plastics films. The plastic may include or be formed from one or more polyolefins (for example high or low density polyethylene (PE) or polypropylene (PP)). Furthermore, the plastic may include or be formed from polyvinyl chloride (PVC), polystyrene (PS), polyester and/or polycarbonate (PC), polyethylene terephthalate (PET), polyethersulfone (PES) and/or polyethylene naphthalate (PEN). The carrier 102 may include one or more of the substances mentioned above. The carrier 102 may include or be formed from a metal or a metal compound, for example copper, silver, gold, platinum or the like.

A carrier 102 including a metal or a metal compound can also be embodied as a metal film or a metal-coated film.

The carrier 102 can be embodied as translucent or even transparent.

In various embodiments, the term “translucent” or “translucent layer” can be understood to mean that a layer is transmissive to light, for example to the light generated by the light emitting component, for example in one or more wavelength ranges, for example to light in a wavelength range of visible light (for example at least in a partial range of the wavelength range of from 380 nm to 780 nm). By way of example, in various embodiments, the term “translucent layer” should be understood to mean that substantially the entire quantity of light coupled into a structure (for example a layer) is also coupled out from the structure (for example layer), wherein part of the light can be scattered in this case.

In various embodiments, the term “transparent” or “transparent layer” can be understood to mean that a layer is transmissive to light (for example at least in a partial range of the wavelength range of from 380 nm to 780 nm), wherein light coupled into a structure (for example a layer) is also coupled out from the structure (for example layer) substantially without scattering or light conversion. Consequently, in various embodiments, “transparent” should be regarded as a special case of “translucent”.

For the case where, for example, a light emitting monochromatic or emission spectrum-limited electronic component is intended to be provided, it suffices for the optically translucent layer structure to be translucent at least in a partial range of the wavelength range of the desired monochromatic light or for the limited emission spectrum.

In various embodiments, the organic light emitting diode 100 (or else the light emitting components in accordance with the embodiments that have been described above or will be described below) can be designed as a so-called top and bottom emitter. A top and/or bottom emitter can also be designated as an optically transparent component, for example a transparent organic light emitting diode.

In various embodiments, a barrier layer 104 can optionally be arranged on or above the carrier 102. The barrier layer 104 may include or consist of one or more of the following substances: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. Furthermore, in various embodiments, the barrier layer 104 can have a layer thickness in a range of approximately 0.1 nm (one atomic layer) to approximately 5000 nm, for example a layer thickness in a range of approximately 10 nm to approximately 200 nm, for example a layer thickness of approximately 40 nm.

An electrically active region 106 of the light emitting component 100 can be arranged on or above the barrier layer 104. The electrically active region 106 can be understood as that region of the light emitting component 100 in which an electric current for the operation of the light emitting component 100 flows. In various embodiments, the electrically active region 106 may include a first electrode 110, a second electrode 114 and an organic functional layer structure 112, as are explained in even greater detail below.

In this regard, in various embodiments, the first electrode 110 (for example in the form of a first electrode layer 110) can be applied on or above the barrier layer 104 (or, if the barrier layer 104 is not present, on or above the carrier 102). The first electrode 110 (also designated hereinafter as bottom electrode 110) can be formed from an electrically conductive substance, such as, for example, a metal or a transparent conductive oxide (TCO) or a layer stack including a plurality of layers of the same metal or different metals and/or the same TCO or different TCOs. Transparent conductive oxides are transparent conductive substances, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs and can be used in various embodiments. Furthermore, the TCOs do not necessarily correspond to a stoichiometric composition and can furthermore be p-doped or n-doped.

In various embodiments, the first electrode 110 may include a metal; for example Ag, Pt, Au, Mg, Al, Ba, In, Ag, Au, Mg, Ca, Sm or Li, and compounds, combinations or alloys of these substances.

In various embodiments, the first electrode 110 can be formed by a layer stack of a combination of a layer of a metal on a layer of a TCO, or vice versa. One example is a silver layer applied on an indium tin oxide layer (ITO) (Ag on ITO) or ITO-Ag-ITO multilayers.

In various embodiments, the first electrode 110 may include one or a plurality of the following substances as an alternative or in addition to the abovementioned substances: networks composed of metallic nanowires and nanoparticles, for example composed of Ag; networks composed of carbon nanotubes; graphene particles and graphene layers; networks composed of semiconducting nanowires.

Furthermore, the first electrode 110 may include electrically conductive polymers or transition metal oxides or transparent electrically conductive oxides.

In various embodiments, the first electrode 110 and the carrier 102 can be formed as translucent or transparent. In the case where the first electrode 110 includes or is formed from a metal, the first electrode 110 can have for example a layer thickness of less than or equal to approximately 25 nm, for example a layer thickness of less than or equal to approximately 20 nm, for example a layer thickness of less than or equal to approximately 18 nm. Furthermore, the first electrode 110 can have for example a layer thickness of greater than or equal to approximately 10 nm, for example a layer thickness of greater than or equal to approximately 15 nm. In various embodiments, the first electrode 110 can have a layer thickness in a range of approximately 10 nm to approximately 25 nm, for example a layer thickness in a range of approximately 10 nm to approximately 18 nm, for example a layer thickness in a range of approximately 15 nm to approximately 18 nm.

Furthermore, for the case where the first electrode 110 includes or is formed from a transparent conductive oxide (TCO), the first electrode 110 can have for example a layer thickness in a range of approximately 50 nm to approximately 500 nm, for example a layer thickness in a range of approximately 75 nm to approximately 250 nm, for example a layer thickness in a range of approximately 100 nm to approximately 150 nm.

Furthermore, for the case where the first electrode 110 is formed from, for example, a network composed of metallic nanowires, for example composed of Ag, which can be combined with conductive polymers, a network composed of carbon nanotubes which can be combined with conductive polymers, or from graphene layers and composites, the first electrode 110 can have for example a layer thickness in a range of approximately 1 nm to approximately 500 nm, for example a layer thickness in a range of approximately 10 nm to approximately 400 nm, for example a layer thickness in a range of approximately 40 nm to approximately 250 nm.

The first electrode 110 can be formed as an anode, that is to say as a hole-injecting electrode, or as a cathode, that is to say as an electron-injecting electrode.

The first electrode 110 can have a first electrical contact pad, to which a first electrical potential (provided by an energy source (not illustrated), for example a current source or a voltage source) can be applied. Alternatively, the first electrical potential can be applied to the carrier 102 and then be applied indirectly to the first electrode 110 via said carrier. The first electrical potential can be, for example, the ground potential or some other predefined reference potential.

Furthermore, the electrically active region 106 of the light emitting component 100 can have an organic functional layer structure 112, which is applied or formed on or above the first electrode 110.

The organic functional layer structure 112 may include one or a plurality of emitter layers 118, for example including fluorescent and/or phosphorescent emitters, and one or a plurality of hole-conducting layers 116 (also designated as hole transport layer(s) 120). In various embodiments, one or a plurality of electron-conducting layers 116 (also designated as electron transport layer(s) 116) can alternatively or additionally be provided.

Examples of emitter materials which can be used in the light emitting component 100 in accordance with various embodiments for the emitter layer(s) 118 include organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl) iridium III), green phosphorescent Ir(ppy)₃ (tris(2-phenylpyridine)iridium III), red phosphorescent Ru (dtb-bpy)₃*2(PF₆) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]anthracene) and red fluorescent DCM2 (4-dicyanomethylene)-2-methyl-6-julolidyl-9-enyl-4H-pyran) as non-polymeric emitters. Such non-polymeric emitters can be deposited by thermal evaporation, for example. Furthermore, it is possible to use polymer emitters, which can be deposited, in particular, by a wet-chemical method such as spin coating, for example.

The emitter materials can be embedded in a matrix material in a suitable manner.

It should be pointed out that other suitable emitter materials are likewise provided in other embodiments.

The emitter materials of the emitter layer(s) 118 of the light emitting component 100 can be selected for example such that the light emitting component 100 emits white light. The emitter layer(s) 118 may include a plurality of emitter materials that emit in different colors (for example blue and yellow or blue, green and red); alternatively, the emitter layer(s) 118 can also be constructed from a plurality of partial layers, such as a blue fluorescent emitter layer 118 or blue phosphorescent emitter layer 118, a green phosphorescent emitter layer 118 and a red phosphorescent emitter layer 118. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

The organic functional layer structure 112 can generally comprise one or a plurality of electroluminescent layers. The one or the plurality of electroluminescent layers may include organic polymers, organic oligomers, organic monomers, organic small, non-polymeric molecules (“small molecules”) or a combination of these substances. By way of example, the organic functional layer structure 112 may include one or a plurality of electroluminescent layers embodied as a hole transport layer 120, so as to enable for example in the case of an OLED an effective hole injection into an electroluminescent layer or an electroluminescent region. Alternatively, in various embodiments, the organic functional layer structure 112 may include one or a plurality of functional layers embodied as an electron transport layer 116, so as to enable for example in an OLED an effective electron injection into an electroluminescent layer or an electroluminescent region. By way of example, tertiary amines, carbazole derivatives, conductive polyaniline or polyethylene dioxythiophene can be used as substance for the hole transport layer 120. In various embodiments, the one or the plurality of electroluminescent layers can be embodied as an electroluminescent layer.

In various embodiments, the hole transport layer 120 can be applied, for example deposited, on or above the first electrode 110, and the emitter layer 118 can be applied, for example deposited, on or above the hole transport layer 120. In various embodiments, the electron transport layer 116 can be applied, for example deposited, on or above the emitter layer 118.

In various embodiments, the organic functional layer structure 112 (that is to say for example the sum of the thicknesses of hole transport layer(s) 120 and emitter layer(s) 118 and electron transport layer(s) 116) can have a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic functional layer structure 112 can have for example a stack of a plurality of organic light emitting diodes (OLEDs) arranged directly one above another, wherein each OLED can have for example a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic functional layer structure 112 can have for example a stack of two, three or four OLEDs arranged directly one above another, in which case for example the organic functional layer structure 112 can have a layer thickness of a maximum of approximately 3 μm.

The light emitting component 100 can optionally generally comprise further organic functional layers, for example arranged on or above the one or the plurality of emitter layers 118 or on or above the electron transport layer(s) 116, which serve to further improve the functionality and thus the efficiency of the light emitting component 100.

The second electrode 114 (for example in the form of a second electrode layer 114) can be applied on or above the organic functional layer structure 112 or, if appropriate, on or above the one or the plurality of further organic functional layer structures.

In various embodiments, the second electrode 114 may include or be formed from the same substances as the first electrode 110, metals being particularly suitable in various embodiments.

In various embodiments, the second electrode 114 (for example for the case of a metallic second electrode 114) can have for example a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm.

The second electrode 114 can generally be formed in a similar manner to the first electrode 110, or differently than the latter. In various embodiments, the second electrode 114 can be formed from one or more of the substances and with the respective layer thickness, as described above in connection with the first electrode 110. In various embodiments, both the first electrode 110 and the second electrode 114 are formed as translucent or transparent. Consequently, the light emitting component 100 illustrated in FIG. 1 can be designed as a top and bottom emitter (to put it another way as a transparent light emitting component 100).

The second electrode 114 can be formed as an anode, that is to say as a hole-injecting electrode, or as a cathode, that is to say as an electron-injecting electrode.

The second electrode 114 can have a second electrical terminal, to which a second electrical potential (which is different than the first electrical potential), provided by the energy source, can be applied. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

An encapsulation 108, for example in the form of a barrier thin-film layer/thin-film encapsulation 108, can optionally also be formed on or above the second electrode 114 and thus on or above the electrically active region 106.

In the context of this application, a “barrier thin-film layer” 108 or a “barrier thin film” 108 can be understood to mean, for example, a layer or a layer structure which is suitable for forming a barrier against chemical impurities or atmospheric substances, in particular against water (moisture) and oxygen. In other words, the barrier thin-film layer 108 is formed in such a way that OLED-damaging substances such as water, oxygen or solvent cannot penetrate through it or at most very small proportions of said substances can penetrate through it.

In accordance with one configuration, the barrier thin-film layer 108 can be formed as an individual layer (to put it another way, as a single layer). In accordance with an alternative configuration, the barrier thin-film layer 108 may include a plurality of partial layers formed one on top of another. In other words, in accordance with one configuration, the barrier thin-film layer 108 can be formed as a layer stack. The barrier thin-film layer 108 or one or a plurality of partial layers of the barrier thin-film layer 108 can be formed for example by a suitable deposition method, e.g. by an atomic layer deposition (ALD) method in accordance with one configuration, e.g. a plasma enhanced atomic layer deposition (PEALD) method or a plasmaless atomic layer deposition (PLALD) method, or by a chemical vapor deposition (CVD) method in accordance with another configuration, e.g. a plasma enhanced chemical vapor deposition (PECVD) method or a plasmaless chemical vapor deposition (PLCVD) method, or alternatively by other suitable deposition methods.

By using an atomic layer deposition (ALD) method, it is possible for very thin layers to be deposited. In particular, layers having layer thicknesses in the atomic layer range can be deposited.

In accordance with one configuration, in the case of a barrier thin-film layer 108 having a plurality of partial layers, all the partial layers can be formed by an atomic layer deposition method. A layer sequence including only ALD layers can also be designated as a “nanolaminate”.

In accordance with an alternative configuration, in the case of a barrier thin-film layer 108 including a plurality of partial layers, one or a plurality of partial layers of the barrier thin-film layer 108 can be deposited by a different deposition method than an atomic layer deposition method, for example by a vapor deposition method.

In accordance with one configuration, the barrier thin-film layer 108 can have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

In accordance with one configuration in which the barrier thin-film layer 108 includes a plurality of partial layers, all the partial layers can have the same layer thickness. In accordance with another configuration, the individual partial layers of the barrier thin-film layer 108 can have different layer thicknesses. In other words, at least one of the partial layers can have a different layer thickness than one or more other partial layers.

In accordance with one configuration, the barrier thin-film layer 108 or the individual partial layers of the barrier thin-film layer 108 can be formed as a translucent or transparent layer. In other words, the barrier thin-film layer 108 (or the individual partial layers of the barrier thin-film layer 108) can consist of a translucent or transparent substance (or a substance mixture that is translucent or transparent).

In accordance with one configuration, the barrier thin-film layer 108 or (in the case of a layer stack having a plurality of partial layers) one or a plurality of the partial layers of the barrier thin-film layer 108 may include or be formed from one of the following substances: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. In various embodiments, the barrier thin-film layer 108 or (in the case of a layer stack having a plurality of partial layers) one or a plurality of the partial layers of the barrier thin-film layer 108 may include one or a plurality of high refractive index substances, to put it another way one or a plurality of substances having a high refractive index, for example having a refractive index of at least 2.

In one configuration, the cover 126, for example composed of glass, can be applied for example by frit bonding (glass frit bonding/glass soldering/seal glass bonding) to the barrier thin-film layer 108 by a conventional glass solder in the geometrical edge regions of the organic optoelectronic component 100.

In various embodiments, an antireflection layer 128 can be formed on or above the barrier thin-film layer 108, wherein the antireflection layer 128 can have a refractive index in a range of approximately 1.5 to approximately 2.5 and a thickness in a range of approximately 1 μm to approximately 100 μm. In one configuration, the antireflection layer 128 may include a substance having an intrinsic refractive index in a range of approximately 1.5 to approximately 2.5. In one configuration, the antireflection layer 128 may include a substance mixture, for example a matrix in which at least one type of additives is distributed. The at least one type of additives can for example be embodied and distributed in the matrix in such a way that the mean refractive index of matrix and additive material is increased in a range of approximately 1.5 to approximately 2.5. In one configuration, the matrix may include at least one further type of additives, wherein the at least one further type of additives can scatter electromagnetic radiation, absorb UV radiation, convert the wavelength of electromagnetic radiation, color the antireflection layer and/or bind harmful substances.

In one configuration, the type of additive material which can bind harmful substances (getter) can be formed in a separate layer on or above the barrier thin-film layer 108. Said layer can also be designated as a getter layer, for example the getter layer 204, 404, wherein the getter layer includes or is formed from a getter. A getter layer including a getter may include for example a getter matrix in which the getter is distributed.

The antireflection layer 128 and the getter can be formed on or above the carrier 102 and/or on or above the barrier thin-film layer 108.

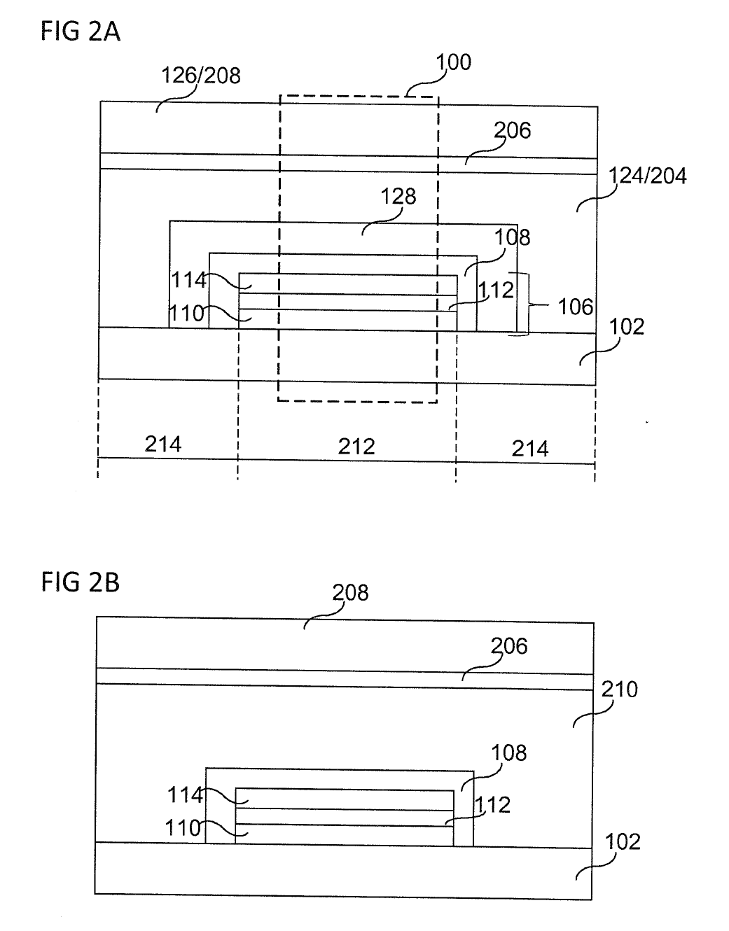

FIG. 2 to FIG. 6 illustrate various embodiments of an optoelectronic component including a getter layer in order to illustrate different configurations with respect to the position of a getter layer in the layer cross section.

By separated antireflection layer 128 and getter layer it is possible to realize efficient coupling-out of light or coupling-in of light from or into the organic functional layer structure, for example if the getter layer cannot be formed with a high refractive index and with a sufficient scattering effect, for example by dispersed scattering particles, without comparable complexity with respect to the formation of the antireflection layer 128.

In various embodiments, on or above the barrier thin-film layer 108, it is possible to provide an adhesive and/or a protective lacquer 124, by which, for example, a cover 126 (for example a glass cover 126, a metal film covering 126, a sealed plastics film cover 126) is fixed, for example adhesively bonded, on or the barrier thin-film layer 108, for example has physical contact with the antireflection layer 128 and/or the getter layer.

In various embodiments, an outer barrier layer can be formed (not illustrated) on or above the cover 126, for example in accordance with one of the configurations of the barrier layer 104 and/or of the barrier thin-film layer 108.

In various embodiments, the optically translucent layer composed of adhesive and/or protective lacquer 124 can have a layer thickness of greater than 1 μm, for example a layer thickness of several μm. In various embodiments, the adhesive may include or be a lamination adhesive.

In various embodiments, light-scattering particles can also be embedded into the layer of the adhesive (also designated as adhesive layer), which particles can lead to a further improvement in the color angle distortion and the coupling-out efficiency. In various embodiments, the light-scattering particles provided can be dielectric scattering particles, for example, such as metal oxides, for example, such as e.g. silicon oxide (SiO₂), zinc oxide (ZnO), zirconium oxide (ZrO₂), indium tin oxide (ITO) or indium zinc oxide (IZO), gallium oxide (Ga₂Oa), aluminum oxide, or titanium oxide. Other particles may also be suitable provided that they have a refractive index that is different than the effective refractive index of the matrix of the translucent layer structure, for example air bubbles, acrylate, or hollow glass beads. Furthermore, by way of example, metallic nanoparticles, metals such as gold, silver, iron nanoparticles, or the like can be provided as light-scattering particles.

In various embodiments, between the second electrode 114 and the layer composed of adhesive and/or protective lacquer 124, an electrically insulating layer (not shown) can also be applied, for example SiN, for example having a layer thickness in a range of approximately 300 nm to approximately 1.5 μm, for example having a layer thickness in a range of approximately 500 nm to approximately 1 μm, in order to protect electrically unstable substances, during a wet-chemical process for example.

In various embodiments, the adhesive can be designed in such a way that it itself has a refractive index which is less than the refractive index of the cover 126. Such an adhesive can be for example a low refractive index adhesive such as, for example, an acrylate which has a refractive index of approximately 1.3. In one configuration, an adhesive can be for example a high refractive index adhesive which includes for example high refractive index, non-scattering particles and has a mean refractive index corresponding approximately to the mean refractive index of the organic functional layer structure, for example in a range of approximately 1.7 to approximately 2.0. Furthermore, a plurality of different adhesives forming an adhesive layer sequence can be provided.

Furthermore, it should be pointed out that, in various embodiments, an adhesive 124 can also be completely dispensed with, for example in configurations in which the cover 126, for example composed of glass, is applied to the barrier thin-film layer 108 by plasma spraying, for example.

FIGS. 2A and 2B show schematic cross-sectional views of optoelectronic components, in accordance with various configurations.

The schematic cross-sectional view in FIGS. 2A and 2B illustrates one embodiment of an optoelectronic component in accordance with one of the configurations from the description of FIG. 1—identified by the excerpt 100 in the cross-sectional view 200.

The carrier 102, the first electrode 110, the organic radio signals layer structure 112, the second electrode 114, the barrier thin-film layer 108 and the antireflection layer 128 can be embodied in accordance with one of the configuration of the descriptions of FIG. 1.

The getter layer 204 may include a getter matrix and at least one type of getter, for example a zeolite. The getter matrix can be embodied in a manner similar to a configuration of the adhesive layer 124 from the descriptions of FIG. 1.

The barrier layer 206 or the protective layer 206 can be embodied in accordance with one of the configurations of the barrier layer 104 and/or the barrier thin-film layer 108 from the description of FIG. 1.

The carrier 208 of the outer barrier layer 206 can be embodied in accordance with one of the configurations of the cover 126 from the description of FIG. 1.

FIG. 2A illustrates a schematic layer cross section of one embodiment of an optoelectronic component in accordance with various configurations.

A first electrode 110 can be formed on or above the carrier 102. An organic functional layer structure 112 can be formed on or above the first electrode 110. A second electrode 114 can be formed on or above the organic functional layer structure 112. A barrier thin-film layer 108 can be formed on or above the second electrode 114.

In the schematically illustrated embodiment, the barrier thin-film layer 108 can be embodied in a structured fashion in such a way that the barrier thin-film layer 108 at least partly surrounds the first electrode 110, the organic functional layer structure 112 and the second electrode 114, for example completely surrounds them together with the carrier 102. In one configuration, the barrier thin-film layer 108 can be unstructured and can additionally be embodied in a planar fashion on or above the carrier 102 without an electrically active region 106 (not illustrated).

The planar region of the carrier 102 with an electrically active region 106 can also be designated as an optically active region 212. The planar region of the optoelectronic component on or above the carrier 102 without an organic functional layer structure 112 can also be designated as an optically inactive region 214.

An antireflection layer 128 can be formed on or above the barrier thin-film layer 108.

The antireflection layer 128 can be formed in such a way that the antireflection layer 128 at least partly surrounds the first electrode 110, the organic functional layer structure 112, the second electrode 114 and the barrier thin-film layer 108, for example completely surrounds them together with the carrier 102.

A getter layer 204 can be formed on or above the antireflection layer 128.

The getter layer 204 can be formed in such a way that the getter layer 204 at least partly surrounds the first electrode 110, the organic functional layer structure 112, the second electrode 114, the barrier thin-film layer 108 and the antireflection layer 128, for example completely surrounds them together with the carrier 102.

An outer barrier layer 206 can be formed on or above the getter layer 204. The outer barrier layer 106 can for example also be designated as a protective layer 206.

The getter layer 204 can be designed for taking up moisture which can penetrate through the outer barrier layer 206 for example via the geometrical edge of the optoelectronic component.

The outer barrier layer 206 can be formed in such a way that the diffusion of moisture into the getter layer 204 is reduced, such that the quantity of diffused water can be permanently bound by the getter of the getter layer 204.

A cover 208 can be formed on or above the outer barrier layer 206. The cover 208 can also be designed as a carrier 208 or substrate 208 of the outer barrier layer 206.

In one configuration, the outer barrier layer 206 can be formed on or above the cover 208 and can be cohesively connected to the getter layer 204, for example by virtue of the getter layer 204 having an adhesive.

In one configuration, the cover 208 with outer barrier layer 206 can be embodied as a barrier film and can be laminated onto the getter layer 204, for example.

In one configuration, the cover 208 with outer barrier layer 206 may include or be formed from an intrinsically, hermetically impermeable substance with respect to at least one harmful substance (for the optically active region), for example a ceramic, a metal and/or a metal oxide, for example in the form of a film, for example a metal film.

The cover 208 with outer barrier layer 206 can prevent ambient moisture from making direct, whole-area contact with the getter layer 204.

Since the magnitude of the area of the side surfaces of the getter layer 204 is small in relation to the areal dimension of the getter layer 204, the direct contact between ambient moisture and the getter layer through the side surfaces of the getter layer 204 can be relatively small, such that the penetrating moisture can permanently be taken up by the getter.

In one configuration, the getter layer 204 can be embodied in such a way that the getter layer 204 has a smaller layer thickness in the edge region of the optoelectronic component, for example in the optically inactive region 214, than in the optically active region 212. Direct contact between the getter layer 204 and ambient moisture can be reduced as a result.

The getter layer 204 and the outer barrier layer 206 can reduce the amount of water, i.e. moisture, which reaches the barrier thin-film layer 108, i.e. both layers in combination can lead to a reduction of the burden of the actual barrier, i.e. the barrier thin-film layer 108, with respect to harmful substances diffusing in. A reliable flexible encapsulation can be realized as a result.

In one configuration, however, the cover 208 and/or the outer barrier layer 206 can also be optional.

FIG. 2B illustrates one embodiment of an optoelectronic component in accordance with various configurations, wherein an antireflection layer 210 is formed on or above the barrier thin-film layer 108, wherein the antireflection layer 210 includes a getter as additive material.

The antireflection layer 210 with getter additive material can be embodied in such a way that the antireflection layer 210 with getter additive material at least partly surrounds the first electrode 110, the organic functional layer structure 112, the second electrode 114 and the barrier thin-film layer 108, for example completely surrounds them together with the carrier 102.

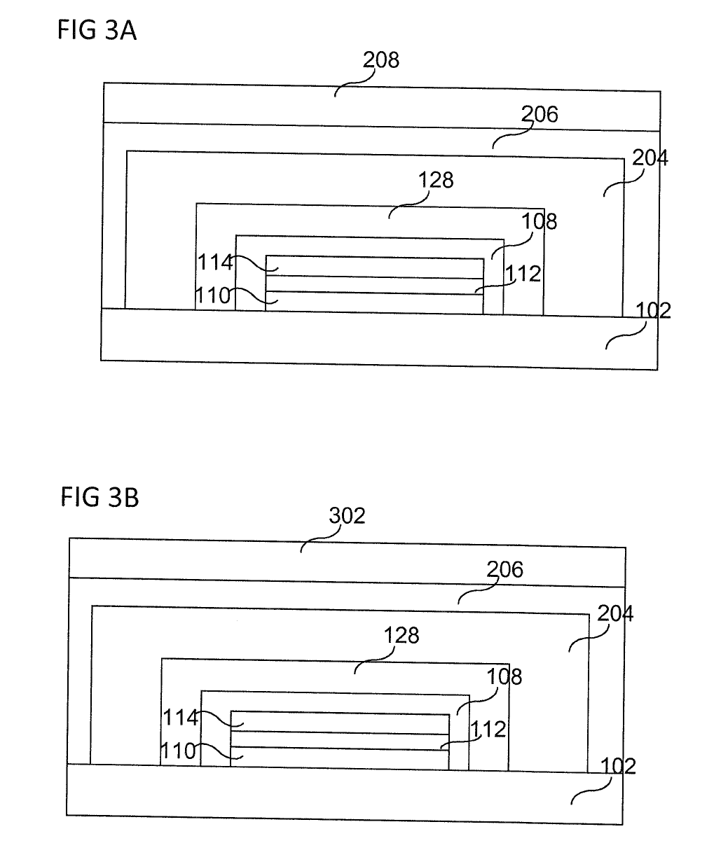

FIGS. 3A and 3B show schematic cross-sectional views of optoelectronic components, in accordance with various configurations.

The type of configuration illustrated in FIGS. 3A and 3B can also be designated as appertaining to the capping side.

The carrier 102, the first electrode 110, the organic radio signals layer structure 112, the second electrode 114, the barrier thin-film layer 108 and the antireflection layer 128 can be embodied in accordance with one of the configuration from the descriptions of FIG. 1 or FIGS. 2A and 2B.

The getter layer 204 can be embodied in accordance with a configuration of the adhesive layer 124 from the descriptions of FIG. 1 and/or the antireflection layer 210 from the description of FIGS. 2A and 2B, wherein the getter layer 204 includes a getter matrix and at least one type of getter.

The outer barrier layer 206 or the protective layer 206 can be embodied in accordance with one of the configurations of the barrier layer 104 and/or the barrier thin-film layer 108 from the description of FIGS. 2A and 2B.

The carrier 208 of the outer barrier layer 206 can be embodied in accordance with one of the configurations of the cover 126 from the description of FIG. 1.

FIG. 3A illustrates a schematic layer cross section of one embodiment of an optoelectronic component, similar to a configuration of the optoelectronic component in FIG. 2A. In addition, the outer barrier layer 206 can surround the side surfaces of the getter layer 204.

In other words: in one configuration, the outer barrier layer 206 can be embodied in such a way that the barrier layer 206 completely surrounds the first electrode 110, the organic functional layer structure 112, the second electrode 114 and the barrier thin-film layer 108, the antireflection layer 128, 210 and/or the getter layer 204 together with the carrier 102.

FIG. 3B illustrates a schematic layer cross section of one embodiment of an optoelectronic component, similar to a configuration of the optoelectronic component in FIG. 3A.

In one embodiment, the cover 208 on or above the outer barrier layer 206 can be embodied as an anti-scratch protection 302. The anti-scratch protection 302 can be embodied in such a way that the optically active region 212 and the optically inactive region 214 are protected against mechanical damage, for example as a metal film, a glass film or a plastics film. In one configuration as anti-scratch protection 302, it is possible for the covering of the outer barrier layer 206 not to be optional.

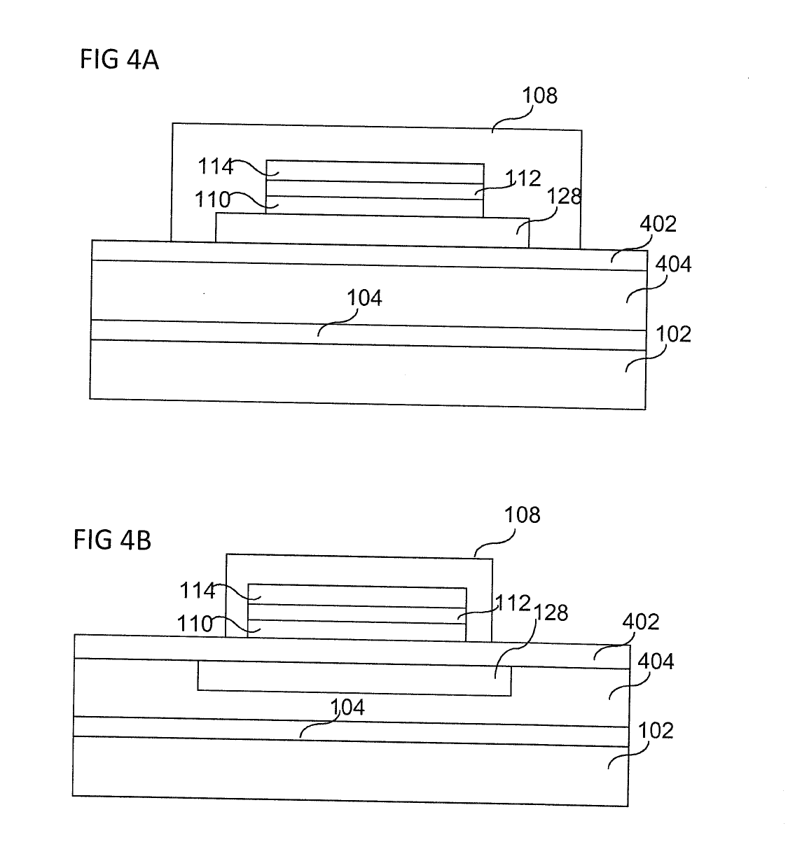

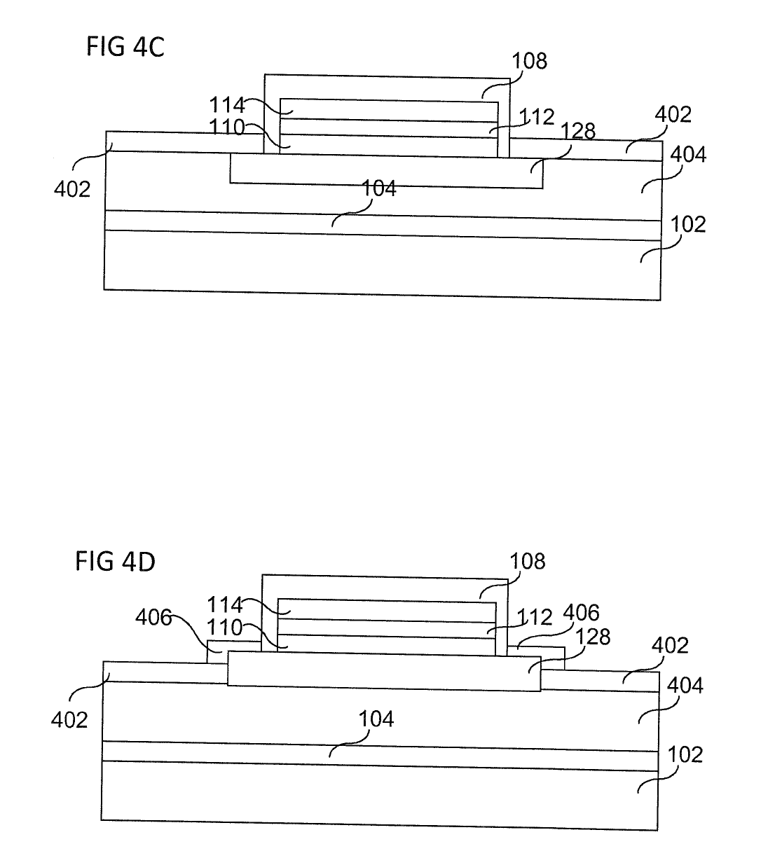

FIGS. 4A to 4D show schematic cross-sectional views of optoelectronic components, in accordance with various configurations.

FIGS. 4A to 4D illustrate embodiments of an optoelectronic component in accordance with various configurations, wherein a getter layer 404 and an antireflection layer 128 can be formed between the carrier 102 and the organic functional layer structure 112. This type of configuration can also be designated as appertaining to the substrate side and be necessary, for example, if the substrate diffusion channels for example with regard to water and/or oxygen.

The carrier 102, the first electrode 110, the organic functional layer structure 112, the second electrode 114, the barrier thin-film layer 108 and the antireflection layer 128 can be embodied in accordance with one of the configuration from the descriptions of FIGS. 1-3.

In accordance with one configuration from the descriptions of FIG. 1, a barrier layer 104 can be formed on or above the carrier 102.

In one configuration, a getter layer 404 can be formed on or above the barrier layer 104, wherein the getter layer 404 can be embodied for example in a manner similar to one of the configurations of the getter layer 204 from the descriptions of FIGS. 2A and 2B.

In one embodiment—illustrated in FIG. 4A—a second protective layer 402 can be formed on or above the getter layer 404, wherein the second protective layer 402 can be embodied in a manner similar to one of the configurations of the first protective layer 206.

In one configuration, however, the second protective layer 402 can also be optional.

The antireflection layer 128 can be formed on or above the second protective layer 402 in accordance with one configuration from the description of FIG. 1, wherein the antireflection layer 128 is at least partly formed in the optically active region.

The organic functional layer structure 106 can be formed on or above the antireflection layer 128. The barrier thin-film layer 108 can be formed on or above the organic functional layer structure 106, wherein the barrier thin-film layer 108 can at least partly surround the organic functional layer structure 106 and the antireflection layer 128, for example can completely surround them together with the carrier 102.

In one embodiment—illustrated in FIG. 4B—the antireflection layer 128 can be formed on or above the getter layer 404 in such a way that the getter layer 404 at least partly surrounds the antireflection layer 128, for example at least partly from below, at least partly laterally and/or at least partly from above, for example completely.

In other words: the antireflection layer 128 can be formed in a getter layer 404 in one configuration, for example can be partly or completely surrounded by a getter layer 404.

In one configuration, the second protective layer 402 can be formed on or above the antireflection layer 128 and the getter layer 404.

In a further embodiment, similar to the embodiment in FIG. 4B, the second protective layer 402 can be structured in such a way that the second protective layer 402 is formed substantially in the optically inactive region 214—illustrated in FIG. 4C.

In other words: the organic functional layer structure 106 can be formed in physical contact with the antireflection layer 128. The barrier thin-film layer 108 and the second protective layer 402 can be embodied in such a way that the surface of the optoelectronic component, for example an optically active side of the optoelectronic component, is partly or completely encapsulated.

In a further embodiments—illustrated in FIG. 4D—the antireflection layer 128, in a manner similar to an embodiment in FIG. 4A, can be formed on or above the second protective layer 402 and the second protective layer 402—in a manner similar to an embodiments in FIG. 4C—can be structured in such a way that a third protective layer 406 is formed on or above the antireflection layer 128.

In other words: the barrier thin-film layer 108, the second protective layer 402 and the third protective layer 406 can be embodied in such a way that the surface of the optoelectronic component, for example an optically active surface, are at least partly surrounded, for example are encapsulated, with the organic functional layer structure 106, the antireflection layer 128 and/or the getter layer 404.

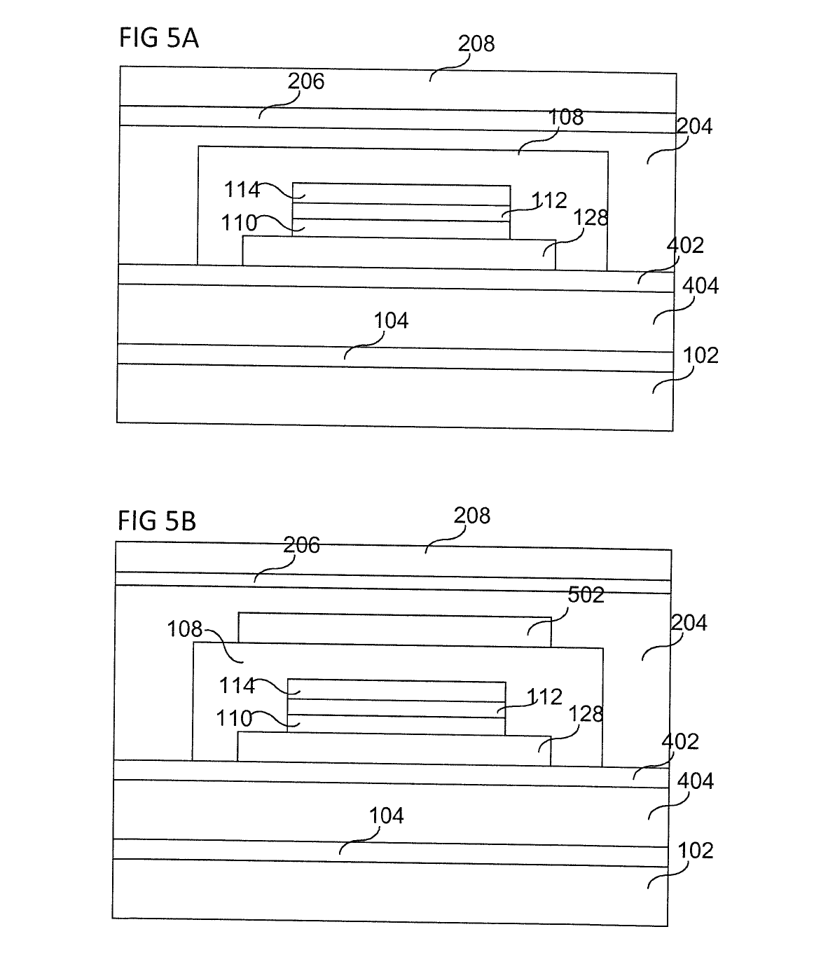

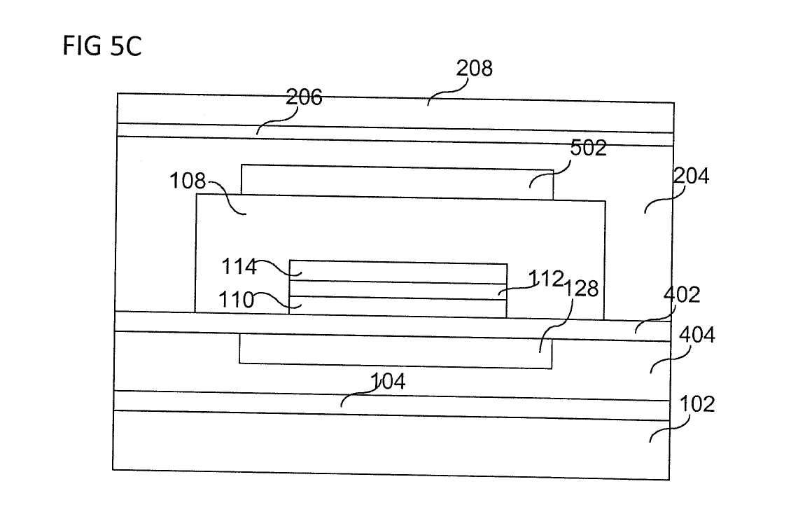

FIGS. 5A to 5C show schematic cross-sectional views of optoelectronic components, in accordance with various configurations.

FIGS. 5A to 5C illustrate embodiments of an optoelectronic component in accordance with various configurations, wherein the optoelectronic component may include getters in a planar fashion, on both sides of the organic functional layer structure 106. This type of configuration can also be designated as appertaining to both sides.

The carrier 102, the first electrode 110, the organic functional layer structure 112, the second electrode 114, the barrier thin-film layer 108 and the antireflection layer 128 can be embodied in accordance with one of the configuration from the descriptions of FIG. 1.

The getter layers 204, 404 can be embodied in accordance with one configuration of the adhesive layer 124 from the descriptions of FIG. 1 and/or the antireflection layer 210 from the description of FIG. 2, wherein the getter layer 204, 404 includes a getter matrix and at least one type of getter.

The barrier layer 104, the protective layer 206, the second protective layer 402 and the barrier thin-film layer 108 can be embodied in accordance with configurations of the barrier thin-film layer 108 from the description of FIG. 1, wherein the barrier layer 104, the first protective layer 206 and the second protective layer 402 can be optional.

The carrier 208 of the outer barrier layer 206 can be embodied in accordance with one of the configurations of the cover 126 from the description of FIG. 1.

In accordance with one configuration of the descriptions from FIG. 1, a barrier layer 104 can be formed on or above the carrier 102. A getter layer 404 can be formed on or above the barrier layer 104, wherein the getter layer 404 can be embodied for example in a manner similar to one of the configurations of the getter layer 204 from the descriptions of FIGS. 2A and 2B.

In one embodiment, the optoelectronic component may include a first getter layer 204 and a second getter layers 404—illustrated in FIG. 5A.

In other words: a plurality of getter layers 204, 404 can be formed in the beam path of the optically active region 212.

In one embodiment, the optoelectronic component may include a second antireflection layer 502 at least partly in the optically active region 212 of the optoelectronic component, wherein the second antireflection layer 502 can be designed for example in a manner similar to the first antireflection layer 128 or similar to the antireflection layer 210 with getter additives.

In other words: a plurality of antireflection layer 128, 502 can be formed in the beam path of the optically active region 212.

In one embodiments—illustrated in FIG. 5C—the optoelectronic component—similar to one configuration from the descriptions of FIG. 4C—may include a first antireflection layer 128, which for example is at least partly surrounded by a second getter layer 404, and a second antireflection layer 502, which for example is at least partly surrounded by a first getter layer 204.

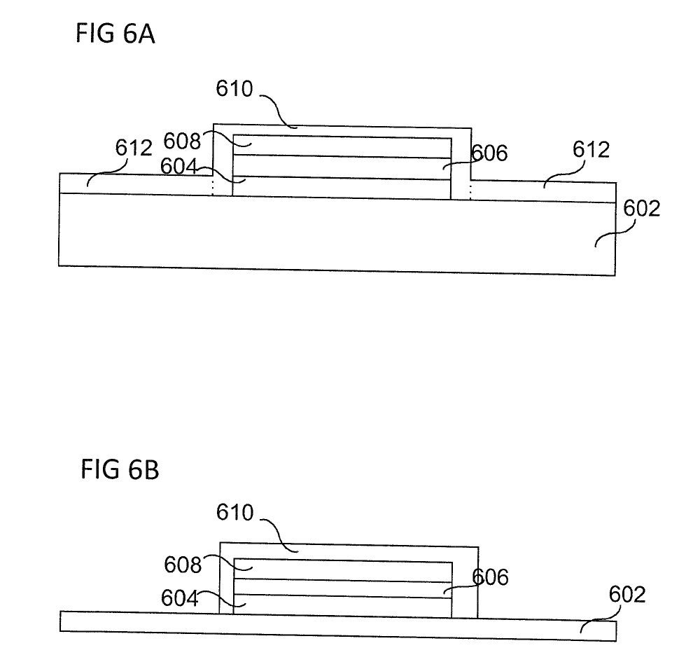

FIGS. 6A and 6B show different configurations of a conventional optoelectronic component.

A first electrode 604 can be formed on or above a carrier 602. An organic functional layer structure 606 can be formed on or above the first electrode 604. A second electrode 608 can be formed on or above the organic functional layer structure 606. An encapsulation layer 610 can be formed on or above the second electrode 608.

The encapsulation layer 610 can be formed in such a way that the barrier thin-film layer 612 together with the carrier 602 completely surrounds the first electrode 604, the organic functional layer structure 606 and the second electrode 608 and is additionally formed in physical contact on or above the carrier 602—illustrated in FIG. 6A.

In a further conventional optoelectronic component—illustrated in FIG. 6B—the encapsulation layer 610 can be structured in such a way that the encapsulation layer 610 together with the carrier 602 completely surrounds only the first electrode 604, the organic functional layer structure 606 and the second electrode 608.

In various embodiments, an optoelectronic component and a method for producing an optoelectronic component are provided which make it possible to increase that proportion of electromagnetic radiation which can be taken up or provided by the optoelectronic component with a getter layer.

A getter layer can have a mean refractive index which is less than the mean refractive index of the organic functional layer structure, can have no scattering effect and/or can have no integration possibility for optical lenses. As a result, a significant portion of the provided electromagnetic radiation can be reflected, for example by total internal reflection, at an interface or the interfaces of the getter layer. The reflected portion of the electromagnetic radiation then cannot be coupled into the optoelectronic component, for example in the case of organic solar cells or organic sensors, or cannot be coupled out from the optoelectronic component, for example in the case of an organic light emitting diode.

The portion of reflected electromagnetic radiation can be reduced by an antireflection layer in the beam path of the optically active region and the getter layer. The antireflection layer may include or be formed from a substance, for example, whereby the antireflection layer has a high mean refractive index, for example a higher mean refractive index than the getter layer. In addition, the antireflection layer can have a scattering effect, for example by a structuring of the interfaces, for example of the surface, for example in a manner similar to an optical lens.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic component, comprising:
a carrier;
an organic functional layer structure, wherein the organic functional layer structure is embodied on or above a carrier and is designed for taking up and/or providing electromagnetic radiation;
an antireflection/getter layer structure arranged in the beam path of the organic functional layer structure and comprising:
getter material having a lower mean refractive index than the mean refractive index of the organic functional layer structure; and
an antireflection layer, wherein material of the antireflection layer is arranged in the beam path of the organic functional layer structure at least partly between the organic functional layer structure and the getter material, and wherein the material of the antireflection layer arranged between the organic functional layer structure and the getter material has a mean refractive index which is greater than the refractive index of the getter material and/or comprises at least one scattering additive material distributed in a matrix.

2. The optoelectronic component as claimed in claim 1,
wherein the organic functional layer structure, the getter and/or the antireflection layer are/is embodied as translucent and/or transparent.

3. The optoelectronic component as claimed in claim 1,
wherein the optoelectronic component is embodied as an organic, optoelectronic component.

4. The optoelectronic component as claimed in claim 1, further comprising:
a first electrode and a second electrode, wherein the organic functional layer structure is arranged electrically between the electrodes.

5. The optoelectronic component as claimed in claim 1, further comprising:
at least one bather thin-film layer between the organic functional layer structure of the organic functional layer structure and the getter.

6. The optoelectronic component as claimed in claim 1,
wherein the getter is embodied in a getter layer, wherein the getter is contained in a getter matrix.

7. The optoelectronic component as claimed in claim 6,
wherein the getter layer has a first thickness in a first region and a second thickness in a second region, wherein the second thickness is less than the first thickness.

8. The optoelectronic component as claimed in claim 7, comprising an optically active region and an optically inactive region, wherein the first region has the optically active region and the second region has the optically inactive region.

9. The optoelectronic component as claimed in claim 8,
wherein the at least one getter layer at least partly surrounds the organic functional layer structure, the at least one barrier thin-film layer and/or the at least one antireflection layer.

10. The optoelectronic component as claimed in claim 1, further comprising:
a protective layer on or above the antireflection layer, wherein the protective layer at least partly surrounds the organic functional layer structure, the at least one bather thin-film layer, the at least one antireflection layer and/or the at least one getter layer.

11. The optoelectronic component as claimed in claim 1, further comprising:
at least two antireflection/getter layer structures, wherein the at least two antireflection/getter layer structures are arranged on or above the same side or on or above different sides of the organic functional layer structure.

12. A method for producing an optoelectronic component, the method comprising:
providing an organic functional layer structure on or above a carrier, wherein the organic functional layer structure is embodied for taking up and/or providing electromagnetic radiation;
forming an antireflection/getter layer structure in the beam path of the organic functional layer structure, the antireflection/getter layer structure comprising:
a getter material having a lower mean refractive index than the organic functional layer structure; and
an antireflection layer, wherein material of the antireflection layer is formed in the beam path of the organic functional layer structure at least partly between the organic functional layer structure and the getter material, and wherein the material of the antireflection layer arranged between the organic functional layer structure and the getter material has a mean refractive index which is greater than the mean refractive index of the getter material and/or comprises at least one scattering additive material distributed in a matrix.

13. The method as claimed in claim 12,
wherein the organic functional layer structure, the getter and/or the antireflection layer are/is embodied as translucent and/or transparent.

14. The method as claimed in claim 12,
wherein the optoelectronic component is embodied as an organic, optoelectronic component.

15. The method as claimed in claim 12, further comprising: forming a first electrode and a second electrode, wherein the organic functional layer structure is formed electrically between the electrodes.

16. The method as claimed in claim 12, further comprising:
forming at least one bather thin-film layer between the organic functional layer structure and the getter.

17. The method as claimed in claim 12, wherein the antireflection layer is formed in such a way that the absolute value of the mean refractive index of the antireflection layer is approximately greater than the absolute value of the mean refractive index of the organic functional layer structure.

18. The optoelectronic component as claimed in claim 1,
wherein the optoelectronic component is embodied as an organic solar cell or an organic light emitting diode.

19. The method as claimed in claim 12,
wherein the optoelectronic component is embodied as an organic solar cell or an organic light emitting diode.
